(19) United States
(12) Patent Application Publication
(10) Pub. No.: US 2025/0255070 A1
(43) Pub. Date: Aug. 7, 2025

(54) DISPLAY DEVICE

(71) Applicants: LG ELECTRONICS INC., Seoul (KR); LG DISPLAY CO., LTD., Seoul (KR)

(72) Inventors: Kisu KIM, Seoul (KR); Kiseong JEON, Seoul (KR)

(73) Assignees: LG ELECTRONICS INC., Seoul (KR); LG DISPLAY CO., LTD., Seoul (KR)

(21) Appl. No.: 18/849,265

(22) PCT Filed: Mar. 22, 2022
(86) PCT No.: PCT/KR2022/003985

§ 371 Date: Sep. 20, 2024

(51) Int. Cl. H10H 29/49; H10H 29/14

(52) U.S. Cl. CPC H10H 29/49; H10H 29/142

(57) ABSTRACT

The display device may include a substrate, a first assembling wiring on the substrate, a second assembling wiring on the substrate, an adjustment member under the second assembling wiring, an insulation layer on the first assembling wiring and the second assembling wiring, a partition wall comprising an assembly hole on the first assembling wiring and the second assembling wiring, and a semiconductor light-emitting element in the assembly hole.

### TECHNICAL FIELD

The embodiment relates to a display device.

### BACKGROUND ART

A large-area display includes a liquid crystal display (LCD), an OLED display, and a micro-LED display.

A micro-LED display is a display that uses micro-LEDs, which are semiconductor light-emitting elements with a diameter or cross-sectional area of 100 μm or less, as display elements.

Since a micro-LED display uses micro-LEDs, which are semiconductor light-emitting elements, as display elements, it has excellent performance in many characteristics such as contrast ratio, response speed, color reproducibility, viewing angle, brightness, resolution, lifespan, luminous efficiency, and luminance.

In particular, a micro-LED display has the advantage of being able to freely adjust the size or resolution and implement a flexible display because the screen can be separated and combined in a modular manner.

However, since a large-area micro-LED display requires millions or more micro-LEDs, there is a technical problem that it is difficult to quickly and accurately transfer micro-LEDs to a display panel.

Recently developed transfer technologies include the pick and place process, the laser lift-off method, and the self-assembly method.

Among these, the self-assembly method is a method in which semiconductor light-emitting elements find their assembly positions in a fluid on their own, which is advantageous for implementing large-screen display devices.

However, research on the technology for manufacturing displays through self-assembly of micro-LEDs is still insufficient.

In particular, in a conventional technology, when rapidly transferring millions or more semiconductor light-emitting elements to a large display, the transfer speed can be improved, but there is a technical problem in that the transfer error rate can increase, which lowers the transfer yield.

In the related technology, a self-assembly transfer process using dielectrophoresis (DEP) is being attempted, but there is a problem in that the self-assembly rate is low due to the unevenness of the DEP force.

On the other hand, according to the non-public internal technology, DEP force is required for self-assembly, but due to the difficulty in uniform control of the DEP force, there is a problem that the semiconductor light-emitting element is tilted to a place other than the correct position in the assembly hole when assembling using self-assembly.

In addition, due to this tilting phenomenon of the semiconductor light-emitting element, there is a problem that the electrical contact characteristics are deteriorated in the subsequent electrical contact process, resulting in a lower lighting rate.

Therefore, according to the non-public internal technology, the DEP force is required for self-assembly, but when the DEP force is used, there is a technical contradiction that the electrical contact characteristics are deteriorated due to the tilting phenomenon of the semiconductor light-emitting element.

In particular, when the size of pixels or sub-pixels is reduced for high resolution, it becomes more difficult to improve the assembly rate through uniform control of the DEP force.

### DISCLOSURE

### Technical Problem

An object of the embodiment is to solve the foregoing and other problems.

Another purpose of the embodiment is to provide a display device having anew structure.

In addition, another object of the embodiment is to provide a display device having a high resolution.

In addition, another object of the embodiment is to provide a display device capable of improving an assembly rate.

In addition, another object of the embodiment is to provide a display device capable of improving lighting rate.

The technical problems of the embodiments are not limited to those described in this item and include those that can be understood through the description of the invention.

### Technical Solution

In order to achieve the above or other objects, according to one aspect of the embodiment, a display device comprising: a substrate; a first assembling wiring on the substrate; a second assembling wiring on the substrate; an adjustment member under the second assembling wiring; an insulation layer on the first assembling wiring and the second assembling wiring; a partition wall comprising an assembly hole on the first assembling wiring and the second assembling wiring; and a semiconductor light-emitting element in the assembly hole.

A thickness of the second assembling wiring may be smaller than a thickness of the first assembling wiring. A thickness of the adjustment member may be a difference value between a thickness of the first assembling wiring and a thickness of the second assembling wiring.

The first assembling wiring and the adjustment member may be disposed on the same layer. The first assembling wiring and the second assembling wiring may be disposed on different layers.

A lower surface of the first assembling wiring and a lower surface of the adjustment member may be positioned on a first horizontal surface, and an upper surface of the first assembling wiring and an upper surface of the second assembling wiring may be positioned on a second horizontal surface parallel to the first horizontal surface.

The adjustment member may comprise at least one or more conductive layer. A width of the adjustment member may be the same as a width of the second assembling wiring.

The adjustment member may comprise a first adjustment region under the second assembling wiring; a second adjustment region disposed between the first assembling wiring and the insulation layer; and a third adjustment region connecting the first adjustment region and the second adjustment region.

The adjustment member may comprise a dielectric layer. A permittivity of the adjustment member may be smaller than a permittivity of the insulation layer.

A thickness of the adjustment member may be smaller than a thickness of the insulation layer. A thickness of the first assembling wiring and a thickness of the second assembling wiring may be the same.

The first assembling wiring and the second assembling wiring may be disposed on different layers.

A lower surface of the first assembling wiring and a lower surface of the first adjustment region may be positioned on a first horizontal surface, and an upper surface of the second adjustment region and an upper surface of the second assembling wiring may be positioned on a second horizontal surface parallel to the first horizontal surface.

A gap between the first assembling wiring and the second assembling wiring may be 3.5 μm or less. The semiconductor light-emitting element may have a diameter of 5 μm or less.

A connection electrode may be included in the assembly hole, and the connection electrode may connect a lower side of the semiconductor light-emitting element to at least one of the first assembling wiring or the second assembling wiring.

An electrode wiring may be included on the semiconductor light-emitting element, and the electrode wiring can be connected to an upper side of the semiconductor light-emitting element.

### Advantageous Effects

The embodiment can implement a high-resolution display.

In order to reduce material costs and secure price competitiveness, the size of the semiconductor light-emitting element 150 must be reduced. For example, the size of the semiconductor light-emitting element can be reduced from 10 μm to 5 μm. In this case, when the size of the semiconductor light-emitting element is reduced, the gap between the first assembling wiring and the second assembling wiring on the substrate must also be reduced in order to assemble the semiconductor light-emitting element with the reduced size.

As illustrated in FIG. 11, the semiconductor light-emitting element 150-1 can be assembled into the assembly hole 340H1 using self-assembly. As illustrated in FIG. 9, the display substrate 305 according to a first embodiment may comprise a plurality of sub-pixels PX1, PX2, and PX3, and at least one assembly hole 340H1, 340H2, and 340H3 may be included in the plurality of sub-pixels PX1, PX2, and PX3, respectively. A first semiconductor light-emitting element 150-1, a second semiconductor light-emitting element 150-2, and a third semiconductor light-emitting element 150-3 may be assembled into the assembly holes 340H1, 340H2, and 340H3, respectively. The shape of each of the assembly holes 340H1, 340H2, and 340H3 may correspond to the shapes of the first semiconductor light-emitting element 150-1, the second semiconductor light-emitting element 150-2, and the third semiconductor light-emitting element 150-3, respectively.

In the self-assembly method, the semiconductor light-emitting element 150-1 can be inserted into the assembly hole 340H1 by the DEP force formed within the assembly hole 340H1. At this time, in order to form the DEP force within the assembly hole 340H1, a part of the first assembling wiring 321, i.e., the first assembly electrode (321a in FIG. 9), and a part of the second assembling wiring 322, i.e., the second assembly electrode 322a, must vertically overlap with the assembly hole 340H1.

As described above, since the size of the semiconductor light-emitting element 150-1 is reduced, the size (or diameter) of the assembly hole 340H1 corresponding to the shape of the semiconductor light-emitting element 150-2 can also be reduced. As the size of the assembly hole 340H1 is reduced, the area of the first assembling wiring 321 and the area of the second assembling wiring 322 that vertically overlap with the assembly hole 340H1 are reduced. As the area of the first assembling wiring 321 and the area of the second assembling wiring 322 vertically overlapping the assembly hole 340H1 decrease, the DEP force formed within the assembly hole 340H1 may decrease. When the DEP force decreases, the semiconductor light-emitting element 150-1 is difficult to pull into the assembly hole 340H1, making assembly difficult. In addition, the semiconductor light-emitting element 150-1 assembled in the assembly hole 340H1 is also likely to fall out of the assembly hole 340H1, which may decrease the assembly rate and thus decrease the lighting rate.

In order to solve this problem, the area of the first assembling wiring 321 and the area of the second assembling wiring 322 vertically overlapping the assembly hole 340H1 may be expanded by making the gap between the first assembling wiring 321 and the second assembling wiring 322 as narrow as possible.

In the embodiment, by disposing the first assembling wiring 321 and the second assembling wiring 322 on different layers, the gap (L1 in FIG. 10) between the first assembling wiring 321 and the second assembling wiring 322 can be reduced to the maximum. For example, the gap L1 between the first assembling wiring 321 and the second assembling wiring 322 can be 3.5 μm or less.

In the embodiment, the adjustment member 311 may be disposed under the second assembling wiring 322. The height of the upper surface of the second assembling wiring 322 may be adjusted to be positioned on the same horizontal surface as the upper surface of the first assembling wiring 321 by the adjustment member 311. By disposing the insulation layer 320 having a permittivity on the first assembling wiring 321 and the second assembling wiring 322 positioned on the same horizontal surface, a symmetrical or uniform the DEP force is formed within the assembly hole 340H1, so that not only the assembly rate of the semiconductor light-emitting element 150-1 during self-assembly may be improved, but also the lighting rate may be improved.

Meanwhile, as illustrated in FIG. 14, the adjustment member 313 having a permittivity may be disposed on the first assembling wiring 321. In this case, while the adjustment member 313 and the insulation layer 320 are disposed on the first assembling wiring 321, the insulation layer 320 may be disposed on the second assembling wiring 322, so that the DEP force on the first assembling wiring 321 and the DEP force on the second assembling wiring 322 can be different, and thus asymmetry or non-uniformity of the DEP force may occur within the assembly hole 340H1.

To solve this problem, the permittivity of the adjustment member 313 may be made smaller than the permittivity of the insulation layer 320, or the thickness of the adjustment member 313 may be made smaller than the thickness of the insulation layer 320, so that the DEP force on the first assembling wiring 321 and the DEP force on the second assembling wiring 322 may be similar or identical. As an example, the DEP force on the first assembling wiring 321 may be reduced, so that the DEP force on the first assembling wiring 321 and the DEP force on the second assembling wiring 322 may be similar or identical. As another example, the DEP force on the first assembling wiring 321 may be reduced and the DEP force on the second assembling wiring 322 may be increased, so that the DEP force on the first assembling wiring 321 and the DEP force on the second assembling wiring 322 may be similar or identical.

Accordingly, a symmetrical or uniform the DEP force may be formed within the assembly hole 340H1, thereby improving the assembly rate and the lighting rate.

Additional scope of applicability of the embodiments will become apparent from the detailed description that follows. However, since various changes and modifications within the idea and scope of the embodiments may be clearly understood by those skilled in the art, the detailed description and specific embodiments, such as preferred embodiments, should be understood as being given by way of example only.

### DESCRIPTION OF DRAWINGS

FIG. 1 illustrates a living room of a house in which a display device according to an embodiment is disposed.

FIG. 2 is a block diagram schematically showing a display device according to an embodiment.

FIG. 3 is a circuit diagram showing an example of a pixel of FIG. 2.

FIG. 4 is an enlarged view of a first panel area in the display device of FIG. 1.

FIG. 5 is an enlarged view of area A2 of FIG. 4.

FIG. 6 is a drawing showing an example of a light-emitting element according to an embodiment being assembled on a substrate by a self-assembly method.

FIG. 7 is a partial enlarged view of area A3 of FIG. 6.

FIGS. 8A to 8B are self-assembly examples in a display device according to the internal technology.

FIG. 8C is a self-assembly photo in a display device according to the internal technology.

FIG. 8D is a drawing showing a tilt phenomenon that occurs during self-assembly of a display device according to the internal technology.

FIG. 9 is a plan view illustrating a display substrate according to a first embodiment.

FIG. 10 is a cross-sectional view illustrating a display substrate according to the first embodiment.

FIG. 11 illustrates a semiconductor light-emitting element being assembled on a display substrate according to the first embodiment during self-assembly.

FIG. 12 illustrates a change in the DEP force according to the diameter of the semiconductor light-emitting element and the assembling wiring interval.

FIGS. 13A to 13F illustrate a method for manufacturing a display substrate according to the first embodiment.

FIG. 14 is a cross-sectional view illustrating a display substrate according to a second embodiment.

FIG. 15 illustrates a semiconductor light-emitting element being assembled on a display substrate according to the second embodiment during self-assembly.

FIG. 16 illustrates a force applied to a semiconductor light-emitting element according to the material or thickness of each of the adjustment member and the first insulation layer.

FIGS. 17A to 17E illustrate a method for manufacturing a display substrate according to the second embodiment.

FIG. 18 is a plan view illustrating a display device according to an embodiment.

FIG. 19 is a cross-sectional view taken along the D1-D2 line of the first sub-pixel in the display device according to the embodiment of FIG. 18.

The sizes, shapes, dimensions, etc. of elements shown in the drawings can differ from actual ones. In addition, even if the same elements are shown in different sizes, shapes, dimensions, etc. between the drawings, this is only an example on the drawing, and the same elements have the same sizes, shapes, dimensions, etc. between the drawings.

### MODE FOR INVENTION

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there can be directly on the other element or be other intermediate elements therebetween.

The display device described in this specification may comprise a TV, a signage, a mobile phone, a smart phone, a head-up display (HUD) for an automobile, a backlight unit for a laptop computer, a display for VR or AR, etc. However, the configuration according to the embodiment described in this specification may be applied to a device capable of displaying, even if it is a new product type developed in the future.

The following describes a light-emitting element according to an embodiment and a display device comprising the same.

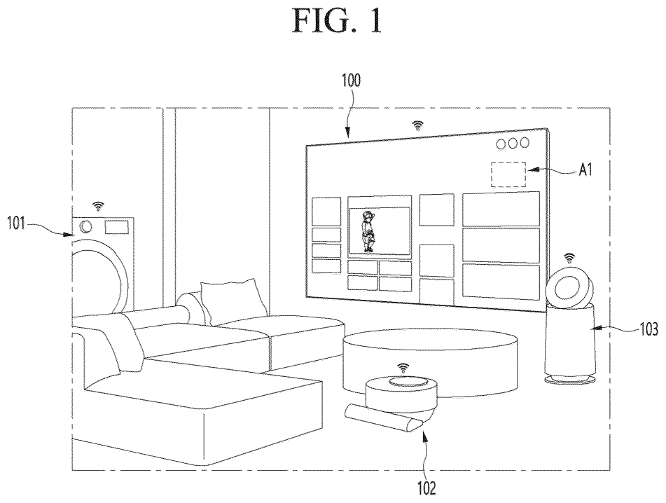

FIG. 1 illustrates a living room of a house in which a display device according to an embodiment is disposed.

Referring to FIG. 1, the display device 100 according to the embodiment can display the status of various electronic products such as a washing machine 101, a robot vacuum cleaner 102, and an air purifier 103, and can communicate with each electronic product based on IoT and control each electronic product based on user setting data.

The display device 100 according to the embodiment can comprise a flexible display manufactured on a thin and flexible substrate. The flexible display can be bent or rolled like paper while maintaining the characteristics of an existing flat panel display.

In the flexible display, visual information can be implemented by independently controlling the light emission of unit pixels disposed in a matrix form. A unit pixel means a minimum unit for implementing one color. The unit pixel of the flexible display can be implemented by a light-emitting element. In the embodiment, the light-emitting element may be a Micro-LED or a Nano-LED, but is not limited thereto.

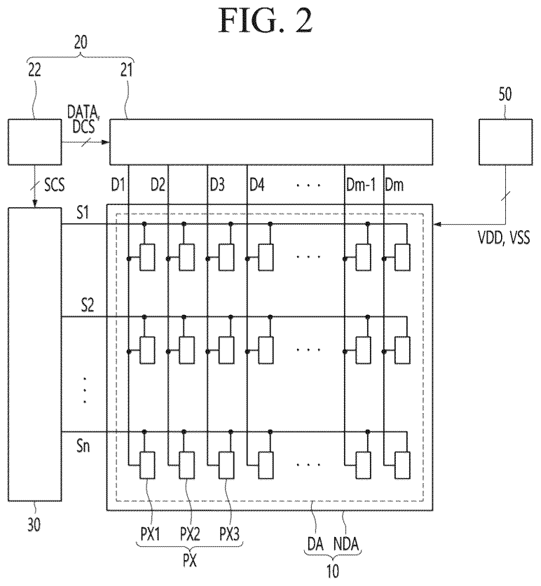

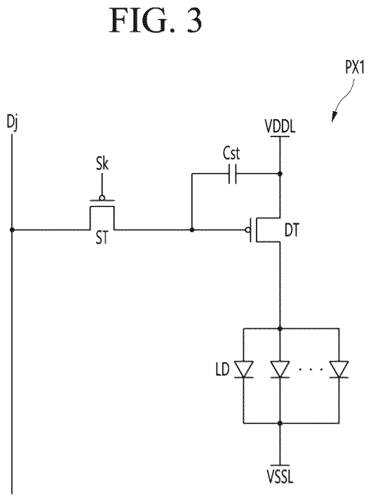

FIG. 2 is a block diagram schematically showing a display device according to an embodiment, and FIG. 3 is a circuit diagram showing an example of a pixel of FIG. 2.

Referring to FIGS. 2 and 3, the display device according to the embodiment may comprise a display panel 10, a driving circuit 20, a scan driving unit 30, and a power supply circuit 50.

The display device 100 of the embodiment may drive the light-emitting element in an active matrix (AM) method or a passive matrix (PM) method.

The driving circuit 20 may comprise a data driving unit 21 and a timing control unit 22.

The display panel 10 may be formed in a rectangular shape, but is not limited thereto. That is, the display panel 10 may be formed in a circular or oval shape. At least one side of the display panel 10 may be formed to be bent at a predetermined curvature.

The display panel 10 can be divided into a display area DA and a non-display area NDA disposed around the display area DA. The display area DA is an area where pixels PX are formed to display an image. The display panel 10 can comprise data lines (D1 to Dm, m is an integer greater than or equal to 2), scan lines (Si to Sn, n is an integer greater than or equal to 2) crossing the data lines D1 to Dm, a high-potential voltage line VDDL to which a high-potential voltage is supplied, a low-potential voltage line VSSL to which a low-potential voltage is supplied, and pixels PX connected to the data lines D1 to Dm and the scan lines S1 to Sn.

Each of the pixels PX can comprise a first sub-pixel PX1, a second sub-pixel PX2, and a third sub-pixel PX3. The first sub-pixel PX1 can emit a first color light of a first main wavelength, the second sub-pixel PX2 can emit a second color light of a second main wavelength, and the third sub-pixel PX3 can emit a third color light of a third main wavelength. The first color light can be red light, the second color light can be green light, and the third color light can be blue light, but is not limited thereto. In addition, in FIG. 2, each of the pixels PX may comprise three sub-pixels, but is not limited thereto. That is, each of the pixels PX may include four or more sub-pixels.

Each of the first sub-pixel PX1, the second sub-pixel PX2, and the third sub-pixel PX3 may be connected to at least one of the data lines D1 to Dm, at least one of the scan lines Si to Sn, and a high-potential voltage line VDDL. The first sub-pixel PX1 may comprise light-emitting elements LD, a plurality of transistors for supplying current to the light-emitting elements LD, and at least one capacitor Cst, as shown in FIG. 3.

Although not shown in the drawing, each of the first sub-pixel PX1, the second sub-pixel PX2, and the third sub-pixel PX3 may comprise only one light-emitting element LD and at least one capacitor Cst.

Each of the light-emitting elements LD may be a semiconductor light-emitting diode comprising a first electrode, a plurality of conductivity type semiconductor layers, and a second electrode. Here, the first electrode may be an anode electrode, and the second electrode may be a cathode electrode, but is not limited thereto.

The light-emitting element LD may be one of a lateral-type light-emitting element, a flip-chip light-emitting element, and a vertical-type light-emitting element.

The plurality of transistors may comprise a driving transistor DT for supplying current to the light-emitting elements LD, and a scan transistor ST for supplying a data voltage to the gate electrode of the driving transistor DT, as shown in FIG. 3. The driving transistor DT may comprise a gate electrode connected to the source electrode of the scan transistor ST, a source electrode connected to a high-potential voltage line VDDL to which a high-potential voltage is applied, and a drain electrode connected to the first electrodes of the light-emitting elements LD. The scan transistor ST may comprise a gate electrode connected to a scan line (Sk, where k is an integer satisfying 1≤k≤n), a source electrode connected to the gate electrode of the driving transistor DT, and a drain electrode connected to a data line (Dj, where j is an integer satisfying 1≤j≤m).

A capacitor Cst is formed between the gate electrode and the source electrode of the driving transistor DT. The storage capacitor Cst charges a difference value between the gate voltage and the source voltage of the driving transistor DT.

The driving transistor DT and the scan transistor ST may be formed as thin film transistors. In addition, in FIG. 3, the driving transistor DT and the scan transistor ST are described mainly as being formed as P-type MOSFET (Metal Oxide Semiconductor Field Effect Transistor), but the present invention is not limited thereto. The driving transistor DT and the scan transistor ST may also be formed as N-type MOSFET. In this case, the positions of the source electrodes and the drain electrodes of each of the driving transistor DT and the scan transistor STs may be changed.

In addition, in FIG. 3, the first sub-pixel PX1, the second sub-pixel PX2, and the third sub-pixel PX3 are exemplified as comprising 2T1C (2 transistor-1 capacitor) having one driving transistor DT, one scan transistor ST, and one capacitor Cst, but the present invention are not limited thereto. The first sub-pixel PX1, the second sub-pixel PX2, and the third sub-pixel PX3 may each comprise a plurality of scan transistors STs and a plurality of capacitors Csts.

Since the second sub-pixel PX2 and the third sub-pixel PX3 can be expressed by substantially the same circuit diagram as the first sub-pixel PX1, a detailed description is omitted.

The driving circuit 20 outputs signals and voltages for driving the display panel 10. To this end, the driving circuit 20 may comprise a data driving unit 21 and a timing control unit 22.

The data driving unit 21 receives digital video data DATA and a source control signal DCS from the timing control unit 22. The data driving unit 21 converts the digital video data DATA into analog data voltages according to the source control signal DCS and supplies the converted data to the data lines D1 to Dm of the display panel 10.

The timing control unit 22 receives digital video data DATA and timing signals from the host system. The timing signals may comprise a vertical synchronization signal, a horizontal synchronization signal, a data enable signal, and a dot clock. The host system may be an application processor of a smartphone or tablet PC, a monitor, a system on chip of a TV, etc.

The timing control unit 22 generates control signals for controlling the operation timing of the data driver 21 and the scan driver 30. The control signals may comprise a source control signal DCS for controlling the operation timing of the data driver 21 and a scan control signal SCS for controlling the operation timing of the scan driver 30.

The driving circuit 20 may be disposed in a non-display area NDA provided on one side of the display panel 10. The driving circuit 20 may be formed as an integrated circuit (IC) and mounted on the display panel 10 using a chip on glass (COG) method, a chip on plastic (COP) method, or an ultrasonic bonding method, but the present invention is not limited thereto. For example, the driving circuit 20 may be mounted on a circuit board (not shown) other than the display panel 10.

The data driving unit 21 may be mounted on the display panel 10 using a chip on glass (COG) method, a chip on plastic (COP) method, or an ultrasonic bonding method, and the timing control unit 22 may be mounted on the circuit board.

The scan driving unit 30 receives a scan control signal SCS from the timing control unit 22. The scan driving unit 30 generates scan signals according to the scan control signal SCS and supplies the scan signals to the scan lines Si to Sn of the display panel 10. The scan driving unit 30 may be formed in a non-display area NDA of the display panel 10 comprising a plurality of transistors. Alternatively, the scan driving unit 30 may be formed as an integrated circuit, in which case it may be mounted on a gate flexible film attached to the other side of the display panel 10.

The circuit board may be attached to pads provided on one edge of the display panel 10 using an anisotropic conductive film. As a result, lead lines of the circuit board may be electrically connected to the pads. The circuit board may be a flexible film such as a flexible printed circuit board, a printed circuit board, or a chip on film. The circuit board may be bent to a lower part of the display panel 10. As a result, one side of the circuit board may be attached to an edge of one side of the display panel 10, and the other side may be disposed on the lower part of the display panel 10 and connected to a system board on which a host system is mounted.

The power supply circuit 50 may generate voltages required for driving the display panel 10 from a main power applied from the system board and supply the voltages to the display panel 10. For example, the power supply circuit 50 can generate a high-potential voltage VDD and a low-potential voltage VSS for driving the light-emitting elements LD of the display panel 10 from the main power supply and supply them to the high-potential voltage line VDDL and the low-potential voltage line VSSL of the display panel 10. In addition, the power supply circuit 50 can generate and supply driving voltages for driving the driving circuit 20 and the scan driving unit 30 from the main power supply.

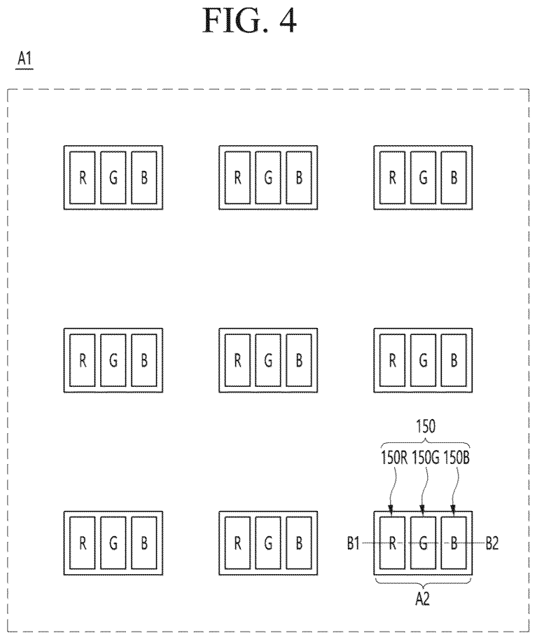

FIG. 4 is an enlarged view of the first panel area in the display device of FIG. 3.

Referring to FIG. 4, the display device 100 of the embodiment can be manufactured by mechanically and electrically connecting a plurality of panel areas such as the first panel area A1 by tiling.

The first panel area A1 can comprise a plurality of semiconductor light-emitting elements 150 disposed for each unit pixel (PX of FIG. 2).

For example, the unit pixel PX may comprise a first sub-pixel PX1, a second sub-pixel PX2, and a third sub-pixel PX3. For example, a plurality of red semiconductor light-emitting elements 150R may be disposed in the first sub-pixel PX1, a plurality of green semiconductor light-emitting elements 150G may be disposed in the second sub-pixel PX2, and a plurality of blue semiconductor light-emitting elements 150B may be disposed in the third sub-pixel PX3. The unit pixel PX may further comprise a fourth sub-pixel in which no semiconductor light-emitting elements are disposed, but is not limited thereto.

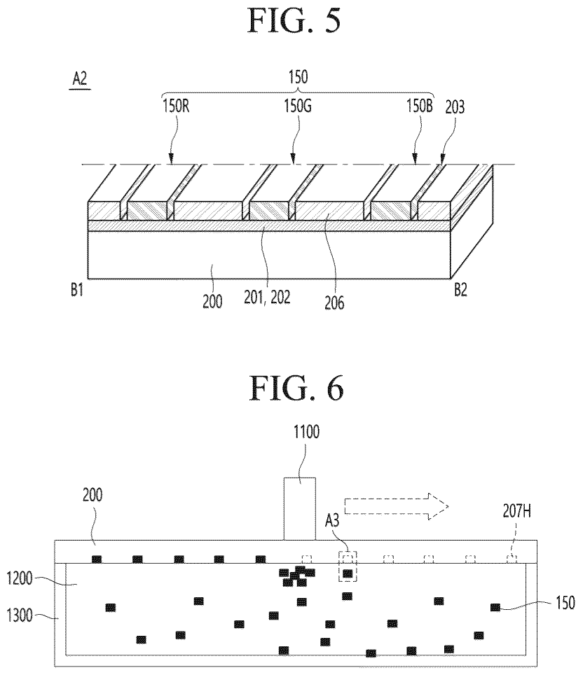

FIG. 5 is an enlarged view of the A2 region of FIG. 4.

Referring to FIG. 5, the display device 100 of the embodiment may comprise a substrate 200, assembling wiring 201 and 202, an insulation layer 206, and a plurality of semiconductor light-emitting elements 150. More components may be included than these.

The assembling wiring may comprise a first assembling wiring 201 and a second assembling wiring 202 that are spaced apart from each other. The first assembling wiring 201 and the second assembling wiring 202 may be provided to generate a dielectrophoretic force (DEP) to assemble the semiconductor light-emitting element 150. For example, the semiconductor light-emitting element 150 may be one of a lateral-type semiconductor light-emitting element, a flip-chip type semiconductor light-emitting element, and a vertical-tye semiconductor light-emitting element.

The semiconductor light-emitting element 150 may comprise a red semiconductor light-emitting element 150, a green semiconductor light-emitting element 150G, and a blue semiconductor light-emitting element 150B to form a unit pixel (sub-pixel), but is not limited thereto, and may also comprise a red phosphor and a green phosphor to implement red and green, respectively.

The substrate 200 may be a support member that supports components disposed on the substrate 200 or a protective member that protects the components.

The substrate 200 may be a rigid substrate or a flexible substrate. The substrate 200 may be formed of sapphire, glass, silicon, or polyimide. In addition, the substrate 200 may comprise a flexible material such as PEN (Polyethylene Naphthalate) or PET (Polyethylene Terephthalate). In addition, the substrate 200 may be a transparent material, but is not limited thereto. The substrate 200 may function as a support substrate in a display panel, and may also function as an assembly substrate during self-assembly of a light-emitting element.

The substrate 200 can be a backplane equipped with circuits in the sub-pixels PX1, PX2 and PX3 shown in FIGS. 2 and 3, such as transistors ST and DT, capacitors Cst, signal wiring, etc., but is not limited thereto.

The insulation layer 206 may comprise an organic material having insulation and flexibility, such as polyimide, PAC, PEN, PET, polymer, or an inorganic material such as silicon oxide (SiO2) or silicon nitride series (SiNx), and may be formed integrally with the substrate 200 to form a single substrate.

The insulation layer 206 may be a conductive adhesive layer having adhesion and conductivity, and the conductive adhesive layer may have flexibility to enable a flexible function of the display device. For example, the insulation layer 206 may be a conductive adhesive layer such as an anisotropic conductive film (ACF) or an anisotropic conductive medium, a solution containing conductive particles, etc. The conductive adhesive layer may be a layer that is electrically conductive in a direction vertical to the thickness, but electrically insulating in a direction horizontal to the thickness.

The insulation layer 206 may comprise an assembly hole 203 for inserting a semiconductor light-emitting element 150. Therefore, when self-assembling, the semiconductor light-emitting element 150 can be easily inserted into the assembly hole 203 of the insulation layer 206. The assembly hole 203 may be called an insertion hole, a fixing hole, an alignment hole, etc. The assembly hole 203 may also be called a hole.

The assembly hole 203 may be called a hole, a groove, a recess, a pocket, etc.

The assembly hole 203 may be different depending on the shape of the semiconductor light-emitting element 150. For example, the red semiconductor light-emitting element, the green semiconductor light-emitting element, and the blue semiconductor light-emitting element have different shapes, respectively, and the assembly hole 203 has a shape corresponding to each shape of these semiconductor light-emitting elements. For example, the assembly hole 203 may comprise a first assembly hole for assembling the red semiconductor light-emitting element, a second assembly hole for assembling the green semiconductor light-emitting element, and a third assembly hole for assembling the blue semiconductor light-emitting element. For example, the red semiconductor light-emitting element may have a circular shape, the green semiconductor light-emitting element may have a first oval shape having a first minor axis and a second major axis, and the blue semiconductor light-emitting element may have a second oval shape having a second minor axis and a second major axis, but are not limited thereto. The second major axis of the oval shape of the blue semiconductor light-emitting element may be greater than the second major axis of the oval shape of the green semiconductor light-emitting element, and the second minor axis of the oval shape of the blue semiconductor light-emitting element may be smaller than the first minor axis of the oval shape of the green semiconductor light-emitting element.

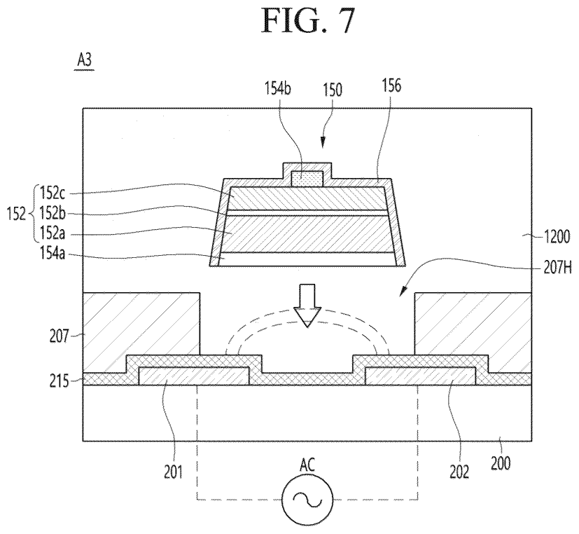

Meanwhile, the method of mounting the semiconductor light-emitting element 150 on the substrate 200 may comprise, for example, a self-assembly method (FIG. 6) and a transfer method.

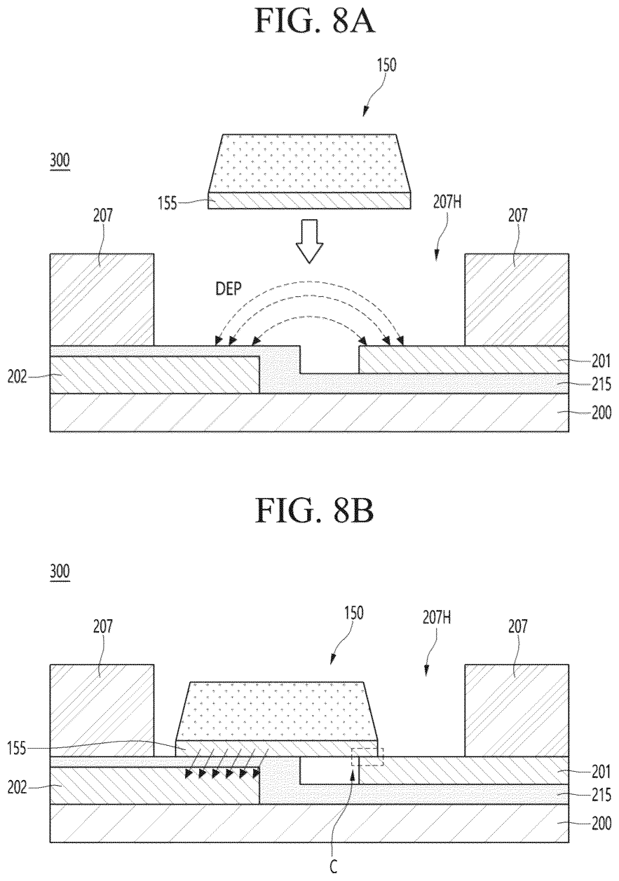

FIG. 6 is a drawing showing an example in which a light-emitting element according to an embodiment is assembled on a substrate by a self-assembly method, and FIG. 7 is a partial enlarged view of area A3 of FIG. 6. FIG. 7 is a drawing in which area A3 is rotated 180 degrees for convenience of explanation.

Based on FIGS. 6 and 7, an example of assembling a semiconductor light-emitting element according to an embodiment into a display panel by a self-assembly method using an electromagnetic field will be described.

The assembly substrate 200 described below can also function as a panel substrate 200a in a display device after assembling the light-emitting element, but the embodiment is not limited thereto.

Referring to FIG. 6, the semiconductor light-emitting element 150 can be put into a chamber 1300 filled with a fluid 1200, and the semiconductor light-emitting element 150 can be moved to the assembly substrate 200 by a magnetic field generated from the assembly device 1100. At this time, the light-emitting element 150 adjacent to the assembly hole 207H of the assembly substrate 200 can be assembled into the assembly hole 207H by the DEP force caused by the electric field of the assembling wirings. The fluid 1200 can be water such as ultrapure water, but is not limited thereto. The chamber can be called a tank, a container, a vessel, etc.

After the semiconductor light-emitting element 150 is put into the chamber 1300, the assembly substrate 200 may be disposed on the chamber 1300. According to an embodiment, the assembly substrate 200 may be put into the chamber 1300.

Referring to FIG. 7, the semiconductor light-emitting element 150 may be implemented as a vertical-type semiconductor light-emitting element as illustrated, but is not limited thereto, and a lateral-type light-emitting element may be employed.

The semiconductor light-emitting element 150 may comprise a magnetic layer (not illustrated) having a magnetic substance. The magnetic layer may comprise a metal having magnetism, such as nickel (Ni). Since the semiconductor light-emitting element 150 put into the fluid comprises the magnetic layer, it may move to the assembly substrate 200 by a magnetic field generated from the assembly device 1100. The magnetic layer may be disposed on the upper side or lower side or both sides of the light-emitting element.

The semiconductor light-emitting element 150 may comprise a passivation layer 156 surrounding the upper surface and the side surface. The passivation layer 156 may be formed by an inorganic insulator such as silica or alumina through PECVD, LPCVD, sputtering deposition, etc. In addition, the passivation layer 156 may be formed by a method of spin coating an organic material such as a photoresist or a polymer material.

The semiconductor light-emitting element 150 may comprise a first conductivity type semiconductor layer 152a, a second conductivity type semiconductor layer 152c, and an active layer 152b disposed therebetween. The first conductivity type semiconductor layer 152a may be an n-type semiconductor layer, and the second conductivity type semiconductor layer 152c may be a p-type semiconductor layer, but is not limited thereto. The first conductivity type semiconductor layer 152a, the second conductivity type semiconductor layer 152c, and the active layer 152b disposed therebetween can form the light-emitting portion 152. The light-emitting portion 152 can be called a light-emitting layer, a light-emitting region, etc.

The first electrode (layer) 154a can be disposed under the first conductivity type semiconductor layer 152a, and the second electrode (layer) 154b can be disposed on the second conductivity type semiconductor layer 152c. To this end, a part of the first conductivity type semiconductor layer 152a or the second conductivity type semiconductor layer 152c can be exposed to the outside. Accordingly, after the semiconductor light-emitting element 150 is assembled on the assembly substrate 200, a part of the passivation layer 156 can be etched in the manufacturing process of the display device.

The first electrode 154a can comprise at least one or more layer. For example, the first electrode 154a may comprise an ohmic layer, a reflective layer, a magnetic layer, a conductive layer, an anti-oxidation layer, an adhesive layer, etc. The ohmic layer may comprise Au, AuBe, etc. The reflective layer may comprise Al, Ag, etc. The magnetic layer may comprise Ni, Co, etc. The conductive layer may comprise Cu, etc. The anti-oxidation layer may comprise Mo, etc. The adhesive layer may comprise Cr, Ti, etc.

The second electrode 154b may comprise a transparent conductive layer. For example, the second electrode 154b may comprise ITO, IZO, etc.

The assembling substrate 200 may comprise a pair of first assembling wiring 201 and second assembling wiring 202 corresponding to each of the semiconductor light-emitting elements 150 to be assembled. Each of the first assembling wiring 201 and the second assembling wiring 202 can be formed by laminating multiple layers of a single metal or metal alloy, metal oxide, etc. For example, each of the first assembling wiring 201 and the second assembling wiring 202 may be formed by comprising at least one of Cu, Ag, Ni, Cr, Ti, Al, Rh, Pd, Ir, Ru, Mg, Zn, Pt, Au, Hf, but is not limited thereto.

In addition, each of the first assembling wiring 201 and the second assembling wiring 202 may be formed by comprising at least one of ITO (indium tin oxide), IZO (indium zinc oxide), IZTO (indium zinc tin oxide), IAZO (indium aluminum zinc oxide), IGZO (indium gallium zinc oxide), IGTO (indium gallium tin oxide), AZO (aluminum zinc oxide), ATO (antimony tin oxide), GZO (gallium zinc oxide), IZON (IZO Nitride), AGZO (Al—Ga ZnO), IGZO (In—Ga ZnO), ZnO, IrOx, RuOx, NiO, RuOx/ITO, Ni/IrOx/Au, and Ni/IrOx/Au/ITO, but is not limited thereto.

The first assembling wiring 201 and the second assembling wiring 202 form an electric field when an AC voltage is applied, and the semiconductor light-emitting element 150 inserted into the assembly hole 207H can be fixed by the DEP force caused by the electric field. The gap between the first assembling wiring 201 and the second assembling wiring 202 can be smaller than the width of the semiconductor light-emitting element 150 and the width of the assembly hole 207H, and the assembly position of the semiconductor light-emitting element 150 can be fixed more precisely using the electric field.

An insulation layer 215 is formed on the first assembling wiring 201 and the second assembling wiring 202 to protect the first assembling wiring 201 and the second assembling wiring 202 from the fluid 1200 and prevent leakage of current flowing in the first assembling wiring 201 and the second assembling wiring 202. For example, the insulation layer 215 may be formed of an inorganic insulator such as silica or alumina, or an organic insulator in a single layer or multiple layers. The insulation layer 215 may have a minimum thickness for preventing damage to the first assembling wiring 201 and the second assembling wiring 202 during assembly of the semiconductor light-emitting element 150, and may have a maximum thickness for stably assembling the semiconductor light-emitting element 150.

A partition wall 207 can be formed on the upper part of the insulation layer 215. A part of the partition wall 207 can be positioned on the upper parts of the first assembling wiring 201 and the second assembling wiring 202, and the remaining part can be positioned on the upper part of the assembling substrate 200.

Meanwhile, when manufacturing the assembling substrate 200, a part of the partition walls formed on the upper part of the insulation layer 215 can be removed, thereby forming an assembly hole 207H in which each of the semiconductor light-emitting elements 150 is coupled and assembled to the assembling substrate 200.

An assembly hole 207H may be formed in the assembling substrate 200, into which semiconductor light-emitting elements 150 are combined, and a surface on which the assembly hole 207H is formed can be in contact with a fluid 1200. The assembly hole 207H can guide an accurate assembly position of the semiconductor light-emitting element 150.

Meanwhile, the assembly hole 207H can have a shape and size corresponding to the shape of the semiconductor light-emitting element 150 to be assembled at a corresponding position. Accordingly, another semiconductor light-emitting element can be assembled in the assembly hole 207H or a plurality of semiconductor light-emitting elements can be prevented from being assembled.

Referring again to FIG. 6, after the assembling substrate 200 is disposed in the chamber, an assembly device 1100 that applies a magnetic field can move along the assembling substrate 200. The assembly device 1100 can be a permanent magnet or an electromagnet.

The assembly device 1100 may move in contact with the assembly substrate 200 to maximize the area affected by the magnetic field within the fluid 1200. DEPending on the embodiment, the assembly device 1100 may comprise a plurality of magnetic substances or may comprise magnetic substance of a size corresponding to the assembly substrate 200. In this case, the movement distance of the assembly device 1100 may be limited within a predetermined range.

The semiconductor light-emitting element 150 within the chamber 1300 may move toward the assembly device 1100 and the assembly substrate 200 by the magnetic field generated by the assembly device 1100.

Referring to FIG. 7, the semiconductor light-emitting element 150 may be fixed by entering the assembly hole 207H by the DEP force formed by the electric field between the assembling wirings 201 and 202 while moving toward the assembly device 1100.

Specifically, the first and second assembling wirings 201 and 202 form an electric field by an AC power source, and the DEP force can be formed between the assembling wirings 201 and 202 by this electric field. The semiconductor light-emitting element 150 can be fixed to the assembly hole 207H on the assembling substrate 200 by this the DEP force.

At this time, a predetermined solder layer (not shown) may be formed between the light-emitting element 150 assembled on the assembly hole 207H of the assembling substrate 200 and the assembling wirings 201 and 202, thereby improving the combining strength of the light-emitting element 150.

In addition, a molding layer (not shown) can be formed on the assembly hole 207H of the assembling substrate 200 after assembly. The molding layer can be a transparent resin or a resin containing a reflective material or a scattering material.

Since the time required for each semiconductor light-emitting element to be assembled on the substrate can be drastically shortened by the self-assembly method using the electromagnetic field described above, a large-area, high-pixel display can be implemented more quickly and economically.

Meanwhile, although not shown, a Vdd line is disposed between the first assembling wiring 201 and the second assembling wiring 202, and can be used as an electrode wiring for electrically contacting the semiconductor light-emitting element 150.

However, as the semiconductor light-emitting element 150 is miniaturized, the gap between the first assembling wiring 201 and the second assembling wiring 202 may also narrow, and when the gap between the first assembling wiring 201 and the second assembling wiring 202 narrows, a problem may occur in which the first assembling wiring 201 or the second assembling wiring 202 is electrically shorted with the Vdd line.

In particular, in order to reduce material costs and secure price competitiveness, the size of the semiconductor light-emitting element 150 may be becoming smaller and smaller, and accordingly, the size of the pixel (or sub-pixel) may be also becoming smaller, so that the gap between the first assembling wiring 201 and the second assembling wiring 202 can be becoming narrower, and thus, the possibility of an electrical short between the first assembling wiring 201 or the second assembling wiring 202 and the Vdd line can be becoming higher.

In addition, when the first assembling wiring 201 and the second assembling wiring 202 are formed on the same layer using a photolithography process, as the gap between the first assembling wiring 201 and the second assembling wiring 202 becomes narrower, the possibility of an electrical short occurring between the first assembling wiring 201 and the second assembling wiring 202 may increase due to exposure limitations. Therefore, there is a problem that it is difficult to form the first assembling wiring 201 and the second assembling wiring 202 on the same layer.

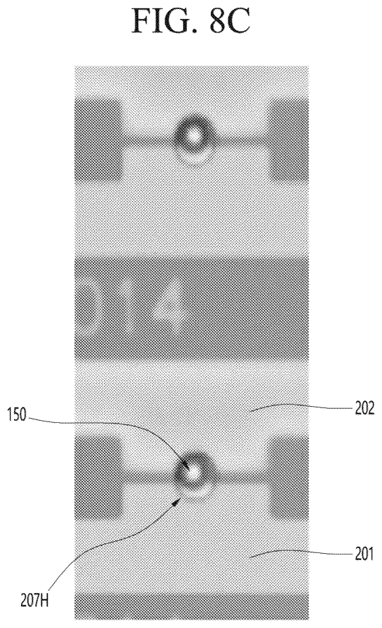

Next, FIGS. 8A to 8B are self-assembly examples of a display device 300 according to the internal technology, and FIG. 8C is a self-assembly photo of a display device according to the internal technology.

In the display device 300 according to the internal technology, either the first assembling wiring 201 or the second assembling wiring 202 is contacted with the bonding metal 155 of the semiconductor light-emitting element 150 through a bonding process.

However, in order to solve the problem that the bonding area is reduced as the semiconductor light-emitting element 150 is miniaturized, as shown in FIGS. 8A to 8B, the existing Vdd line is omitted and its role is opened to one side of the assembling wiring, for example, the first assembling wiring 201. Since the Vdd line is omitted, the gap between the first assembling wiring 201 and the second assembling wiring 202 can be further narrowed, which can easily respond to miniaturization of the semiconductor light-emitting element 150.

However, if this method is used, the semiconductor light-emitting element 150, which is drawn to the first assembling wiring 201 by DEP in the fluid, comes into contact with the first assembling wiring 201 to become conductive. Accordingly, there is a problem that the electric field force is concentrated on the second assembling wiring 202, which is not opened by the insulation layer 215, and as a result, the assembly is biased in one direction.

Referring to FIG. 8B and FIG. 8C, the contact area C between the bonding metal 155 of the semiconductor light-emitting element 150 and the first assembling wiring 201, which functions as a panel electrode, is very small, which may cause poor contact.

That is, according to the non-public internal technology, the DEP force is required for self-assembly, but due to the difficulty in uniformly controlling the DEP force, there is a problem that the semiconductor light-emitting element is tilted to a place other than the correct position within the assembly hole 207H when assembling using self-assembly.

In addition, due to this tilting phenomenon of the semiconductor light-emitting element, the electrical contact characteristics are deteriorated in the subsequent electrical contact process, resulting in poor lighting rate and reduced yield.

Therefore, according to the non-public internal technology, the DEP force is required for self-assembly, but when using the DEP force, there is a technical contradiction in that the electrical contact characteristics are deteriorated due to the tilting phenomenon of the semiconductor light-emitting element.

Next, FIG. 8D is a drawing showing a tilt phenomenon that may occur during self-assembly according to the internal technology.

According to the internal technology, an insulation layer 215 is disposed on the first and second assembling wirings 201 and 202 on the assembling substrate 200, and self-assembly of the semiconductor light-emitting element 150 by the DEP force is performed in the assembly hole 207H set by the assembly partition wall 207. However, according to the internal technology, the electric field force is concentrated on the second assembling wiring 202, resulting in a problem of assembly being biased in one direction, and thus the self-assembly is not performed properly and the problem of tilting within the assembly hole 207H was studied.

The embodiment can improve the lighting rate by increasing the assembly rate while implementing a high resolution.

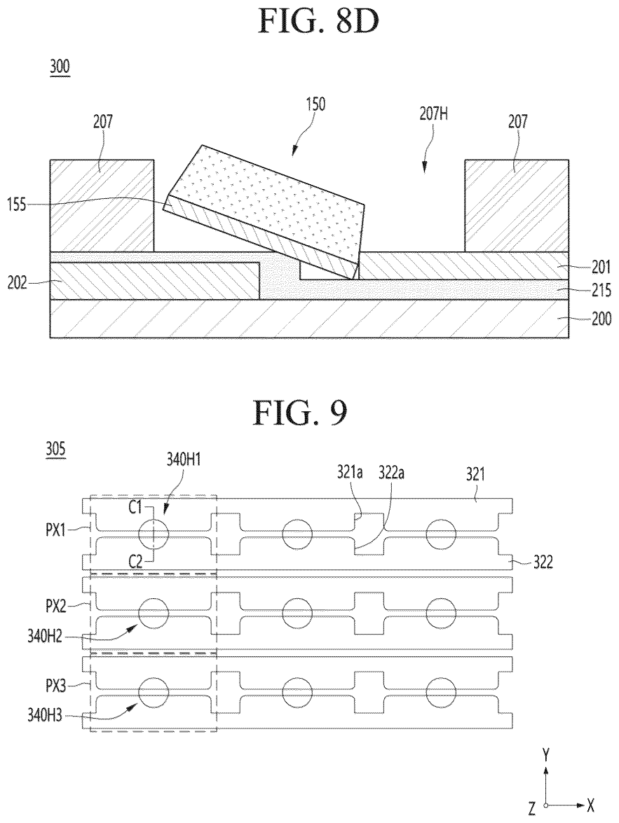

Hereinafter, various embodiments for achieving the above-described technical task will be described with reference to FIGS. 9 to 19. Any omitted descriptions herein can be easily understood from the descriptions given above in relation to FIGS. 1 to 8 and the corresponding drawings.

### First Embodiment

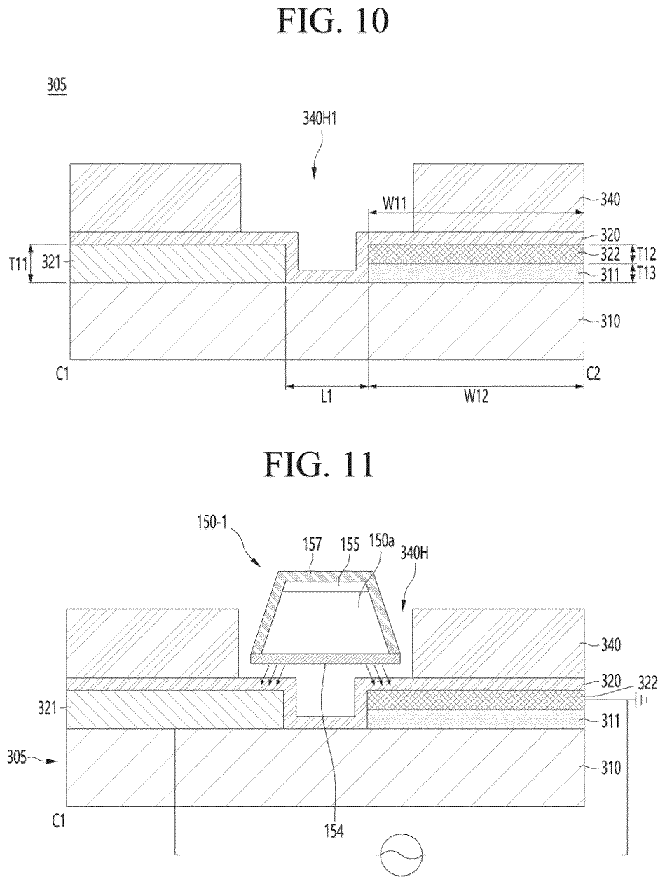

FIG. 9 is a plan view illustrating a display substrate according to a first embodiment. FIG. 10 is a cross-sectional view illustrating a display substrate according to the first embodiment.

Referring to FIGS. 9 and 10, the display substrate 305 according to the first embodiment may be a substrate for assembling tens of millions of semiconductor light-emitting elements for implementing a display through self-assembly. To this end, the display substrate 305 according to the first embodiment may comprise a substrate 310, a first assembling wiring 321, a second assembling wiring 322, an adjustment member 311, an insulation layer 320, and a partition wall 340.

A plurality of sub-pixels PX1, PX2, and PX3 may be arranged on the substrate 310.

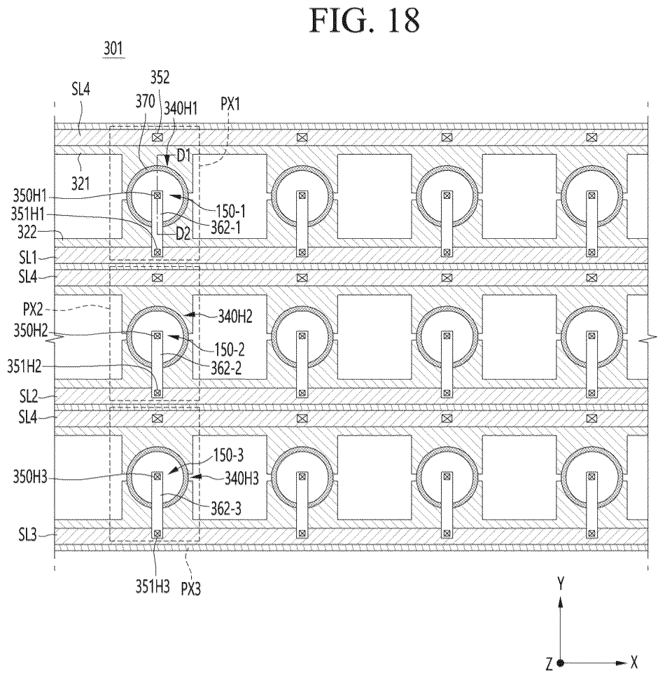

The plurality of sub-pixels may comprise a plurality of first sub-pixels PX1 arranged along the first direction X. The plurality of first sub-pixels PX1 can each emit the same color light, i.e., the first color light. That is, a first semiconductor light-emitting element (150-1 of FIG. 18) for emitting the first color light can be disposed in each of the plurality of first sub-pixels PX1.

For example, the plurality of sub-pixels can comprise a plurality of second sub-pixels PX2 adjacent to each of the plurality of first sub-pixels PX1 along the second direction Y and arranged along the first direction X. The plurality of second sub-pixels PX2 can each emit the same color light, i.e., the second color light. That is, a second semiconductor light-emitting element 150-2 for emitting the second color light can be disposed in each of the plurality of second sub-pixels PX2.

For example, the plurality of sub-pixels may comprise a plurality of third sub-pixels PX3 arranged along the first direction X and adjacent to the second direction Y in each of the plurality of second sub-pixels PX2. The plurality of third sub-pixels PX3 may emit the same color light, i.e., third color light. That is, a third semiconductor light-emitting element 150-3 for emitting the third color light may be disposed in each of the plurality of third sub-pixels PX3.

For example, the first color light may be red light, the second color light may be green light, and the third color light may be blue light, but are not limited thereto. The first sub-pixel PX1, the second sub-pixel PX2, and the third sub-pixel PX3 arranged along the second direction Y may constitute a unit pixel capable of displaying a full color image. Therefore, by arranging a plurality of unit pixels on the substrate 310, a large-area image may be displayed.

FIG. 10 illustrates components included in the first sub-pixel PX1. Although not shown, the second sub-pixel PX2 and the third sub-pixel PX3 may also comprise the components of the first sub-pixel PX1. However, the second sub-pixel PX2 may have a second semiconductor light-emitting element 150-2 disposed thereon, and the third sub-pixel PX3 may have a third semiconductor light-emitting element 150-3 disposed thereon.

The substrate 310 may be a supporting member that supports the components disposed on the substrate 310 or a protective member that protects the components. Since the substrate 310 has been described above, it is omitted.

The first and second assembling wirings 321 and 322 may be disposed on the substrate 310. That is, the plurality of sub-pixels PX1, PX2, and PX3 may each comprise the first assembling wiring 321 and the second assembling wiring 322. The first and second assembling wirings 321 and 322 may play a role in assembling the semiconductor light-emitting element 150-1 into the assembly hole 340H in the self-assembly method. That is, when self-assembling, an electric field is generated between the first assembling wiring 321 and the second assembling wiring 322 by a voltage supplied to the first and second assembling wirings 321 and 322, and the first semiconductor light-emitting element 150-1 moving by the assembly device (1100 of FIG. 6) may be assembled into the assembly hole 340H1 by the DEP force formed by the electric field.

Meanwhile, the first assembling wiring 321 and the second assembling wiring 322 may be disposed long along the first direction X. The first assembling wiring 321 and the second assembling wiring 322 may be disposed parallel to each other. The first assembling wiring 321 and the second assembling wiring 322 may each protrude toward the assembly hole. The protruding region may be referred to as assembly electrode 321a and 322a or protrusion part. The assembly electrode 321a and 322a may be included in the first assembling wiring 321 or the second assembling wiring 322.

The first assembly electrode 321a and the second assembly electrode 322a may each vertically overlap with the assembly hole 340H1. For example, a part of the first assembly electrode 321a may vertically overlap with the assembly hole 340H1 and another part may not vertically overlap with the assembly hole 340H1. For example, a part of the second assembly electrode 322a may vertically overlap with the assembly hole 340H1 and another part may not vertically overlap with the assembly hole 340H1.

The first assembling wiring 321 and the second assembling wiring 322 may be disposed in different layers. That is, an adjustment member 311 may be disposed between the second assembling wiring 322 and the substrate 310. Accordingly, the first assembling wiring 321 may be disposed on the substrate 310, and the second assembling wiring 322 may be disposed on the adjustment member 311.

The adjustment member 311 may be a member that adjusts the height of the upper surface of the second assembling wiring 322. For example, the adjustment member 311 may be a member that adjusts the height of the upper surface of the second assembling wiring 322 so that it is positioned on the same horizontal surface as the upper surface of the first assembling wiring 321.

The thickness T11 of the first assembling wiring 321 and the thickness T12 of the second assembling wiring 322 may be different. For example, the thickness T12 of the second assembling wiring 322 may be smaller than the thickness T11 of the first assembling wiring 321. For example, the thickness T11 of the first assembling wiring 321 may be the sum of the thickness T12 of the second assembling wiring 322 and the thickness T13 of the adjustment member 311. For example, the thickness T13 of the adjustment member 311 may be a difference value between the thickness T11 of the first assembling wiring 321 and the thickness T12 of the second assembling wiring 322.

The first assembling wiring 321 and the adjustment member 311 may be disposed on the same layer. For example, the first assembling wiring 321 and the adjustment member 311 may be disposed on the substrate 310.

The lower surface of the first assembling wiring 321 and the lower surface of the adjustment member 311 may be positioned on the first horizontal surface, for example, the upper surface of the substrate 310. The upper surface of the second assembling wiring 322 and the upper surface of the second assembling wiring 322 may be positioned on the second horizontal surface. The second horizontal surface may be parallel to the first horizontal surface.

Meanwhile, each of the first assembling wiring 321 and the second assembling wiring 322 may be composed of at least one or more layer comprising a metal. The first assembling wiring 321 and the second assembling wiring 322 may comprise the same metal, but is not limited thereto.

According to an embodiment, the first assembling wiring 321 and the second assembling wiring 322 may be disposed in different layers. Accordingly, the first assembling wiring 321 and the second assembling wiring 322 may be formed independently. For example, the first assembling wiring 321 may be formed on the substrate 310 using a first photolithography process. Thereafter, after the adjustment member 311 is formed, the second assembling wiring 322 may be formed. The second assembling wiring 322 may be formed using a second photolithography process. Since the first assembling wiring and the second assembling wiring 322 are formed independently, the second assembling wiring 322 can be formed as close to the first assembling wiring 321 as possible without an electrical short circuit. For example, the gap L1 between the first assembling wiring 321 and the second assembling wiring 322 can be 3.5 μm or less.

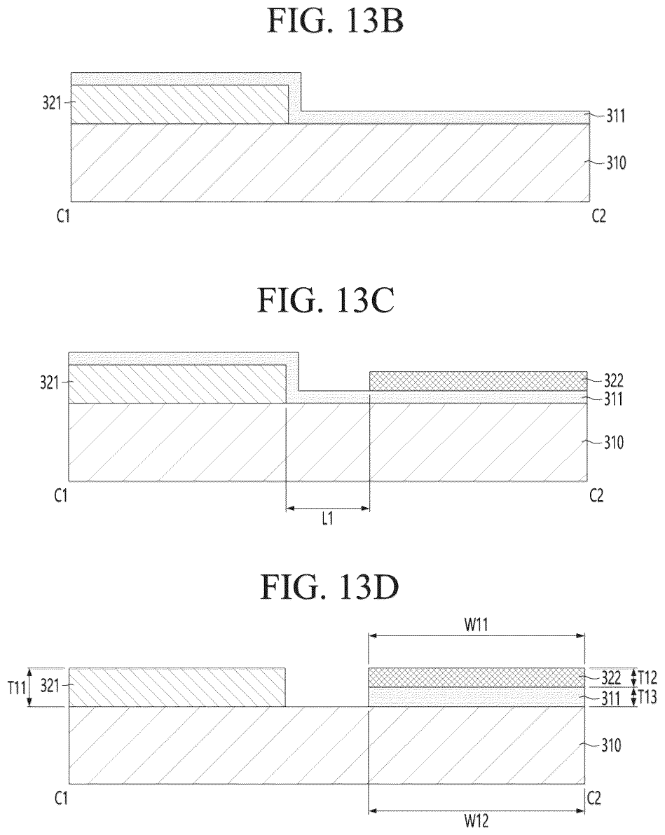

As illustrated in FIG. 12, it can be seen that the DEP force is different depending on the diameter of the semiconductor light-emitting element (150-1, 150-2, 150-3 of FIG. 18) and the assembling wiring gap L1. In FIG. 12, the chip may refer to the semiconductor light-emitting element 150-1, 150-2, and 150-3 of the embodiment.

For example, when the diameter of the semiconductor light-emitting element is 10 μm, when the gap L1 between the first assembling wiring 321 and the second assembling wiring 322 is 8.5 μm or less, the semiconductor light-emitting element assembled in the assembly hole 340H1 may not fall out of the assembly hole 340H1. For example, when the diameter of the semiconductor light-emitting element is 7 μm, when the gap L1 between the first assembling wiring 321 and the second assembling wiring 322 is 5.5 μm or less, the semiconductor light-emitting element assembled in the assembly hole 340H1 may not fall out of the assembly hole 340H1. For example, when the diameter of the semiconductor light-emitting element is 5 μm, when the gap L1 between the first assembling wiring 321 and the second assembling wiring 322 is 3.5 μm or less, the semiconductor light-emitting element assembled in the assembly hole 340H1 may not fall out of the assembly hole 340H1.

By disposing the first assembling wiring 321 and the second assembling wiring 322 in different layers, the condition required to prevent the detachment of the semiconductor light-emitting element assembled in the assembly hole 340H1 when the diameter of the semiconductor light-emitting element is 5 μm or less can be satisfied. That is, since the gap L1 between the first assembling wiring 321 and the second assembling wiring 322 is designed to be 3.5 μm without an electrical short, a display having a high resolution can be implemented.

Meanwhile, the adjustment member 311 can serve as an electrode that supplies voltage together with the second assembling wiring 322.

The adjustment member 311 can comprise at least one or more conductive layer. For example, the adjustment member 311 can comprise a metal. For example, the adjustment member 311 can comprise a conductive oxide, such as ITO.

Since the thickness T12 of the second assembling wiring 322 is smaller than the thickness T11 of the first assembling wiring 321, the resistance of the second assembling wiring 322 may be smaller than the resistance of the first assembling wiring 321. Here, the resistance may be a line resistance or a surface resistance. In this case, since the current supply is not smoother in the second assembling wiring 322 than in the first assembling wiring 321, an asymmetry in the current supply between the first assembling wiring 321 and the second assembling wiring 322 may occur, which may cause an asymmetry in the DEP force within the assembly hole 340H1. The asymmetry may mean an imbalance or an unevenness.

According to the embodiment, an adjustment member 311 comprising at least one or more conductive layer may be disposed under the second assembling wiring 322 to reduce the resistance of the second assembling wiring 322, so that the current supply between the first assembling wiring 321 and the second assembling wiring 322 can be symmetrical, and the DEP force within the assembly hole 340H1 can also be symmetrical. In this way, since the DEP force is symmetrical within the assembly hole 340H1, not only can the semiconductor light-emitting element (150-1, 150-2, 150-3 of FIG. 18) be assembled in the correct position within the assembly hole, but also the phenomenon of the semiconductor light-emitting element assembled within the assembly hole being tilted to one side can be prevented. Accordingly, the assembly rate and the lighting rate of the semiconductor light-emitting element can be improved.

Meanwhile, the width W12 of the adjustment member 311 can be the same as the width W11 of the second assembling wiring 322, but is not limited thereto. As will be explained later, since the etching process is performed using the second assembling wiring 322 as a mask to form the adjustment member 311, the width W11 of the second assembling wiring 322 and the width W12 of the adjustment member 311 can be the same. Accordingly, a separate mask process is not required, so that the process can be simple and the process time can be shortened.

Referring again to FIGS. 9 and 10, the insulation layer 320 may be disposed on the first assembling wiring 321 and the second assembling wiring 322. For example, the insulation layer 320 may prevent the first assembling wiring 321 and the second assembling wiring 322 from being electrically shorted. That is, the insulation layer 320 may be disposed between the first assembling wiring 321 and the second assembling wiring 322. For example, the insulation layer 320 may contact the substrate 310 between the first assembling wiring 321 and the second assembling wiring 322. Accordingly, an electrical short between the first assembling wiring 321 and the second assembling wiring 322 may be prevented by the insulation layer 320 disposed between the first assembling wiring 321 and the second assembling wiring 322. In addition, since the first assembling wiring 321 and the second assembling wiring 322 are not exposed to the outside through the assembly hole 340H1 by the insulation layer 320, an electrical short between the first assembling wiring 321 and the second assembling wiring 322 caused by a foreign substance can also be prevented.

For example, the insulation layer 320 is made of a material having a permittivity, and can contribute to the formation of the DEP force. For example, the insulation layer 320 can be made of an inorganic material or an organic material. For example, the insulation layer 320 can be made of a material having a permittivity related to the DEP force.

Meanwhile, the insulation layer 320 can be formed on the upper surface of the first assembling wiring 321 and the upper surface of the second assembling wiring 322 positioned on the second horizontal surface. Accordingly, since the upper surface of the insulation layer 320 has a horizontal surface, the semiconductor light-emitting elements (150-1, 150-2, 150-3 of FIG. 18) can be disposed without tilt on the bottom surfaces of the assembly holes 340H1, 340H2, and 340H3 of each of the plurality of sub-pixels PX1, PX2, and PX3, i.e., the upper surface of the insulation layer 320, thereby preventing assembly defects and improving the assembly rate.

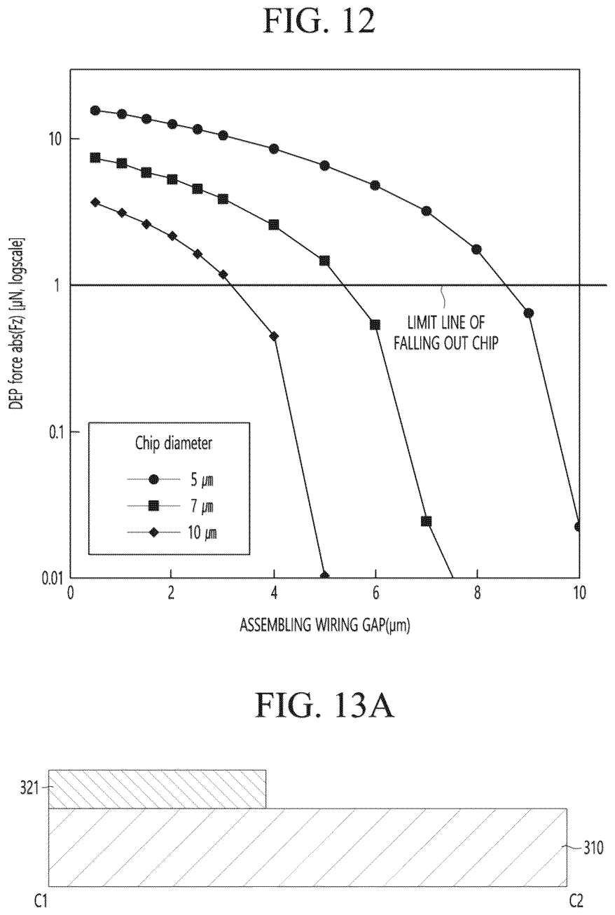

In particular, the thickness of the insulation layer 320 disposed on the upper surface of the first assembling wiring 321 and the upper surface of the second assembling wiring 322 positioned on the second horizontal surface may be constant. In this case, as illustrated in FIG. 11, when an AC voltage is supplied between the first assembling wiring 321 and the second assembling wiring 322 during self-assembly, the DEP force formed on the first assembling wiring 321 and the DEP force formed on the second assembling wiring 322 can be the same. Accordingly, since the DEP forces formed in the assembly holes 340H1, 340H2, and 340H3 of the plurality of sub-pixels PX1, PX2, and PX3, respectively, is uniform, the semiconductor light-emitting elements (150-1, 150-2, and 150-3 of FIG. 18) can be assembled in the correct positions within the assembly holes by the uniform DEP forces during self-assembly, and the phenomenon of the semiconductor light-emitting elements assembled within the assembly holes being tilted to one side can be prevented. Accordingly, the assembly rate and the lighting rate of the semiconductor light-emitting element can be improved.

The partition wall 340 may be disposed on the substrate 310 and may have the assembly hole 340H1. As illustrated in FIG. 9, the plurality of sub-pixels PX1, PX2, and PX3 may each comprise at least one or more assembly hole 340H1, 340H2, and 340H3. The partition wall 340 may be disposed on the first assembling wiring 321 and the second assembling wiring 322. For example, the first assembly hole 340H1 may be provided on the first assembling wiring 321 and the second assembling wiring 322 of the first sub-pixel PX1. For example, the second assembly hole 340H2 may be provided on the first assembling wiring 321 and the second assembling wiring 322 of the second sub-pixel PX2. For example, the third assembly hole 340H3 may be provided on the first assembling wiring 321 and the second assembling wiring 322 of the third sub-pixel PX3.

In this case, a first semiconductor light-emitting element (150-1 of FIG. 18) may be disposed in the first assembly hole 340H1 of the first sub-pixel PX1, a second semiconductor light-emitting element 150-2 may be disposed in the second assembly hole 340H2 of the second sub-pixel PX2, and a third semiconductor light-emitting element 150-3 may be disposed in the third assembly hole 340H3 of the third sub-pixel PX3.

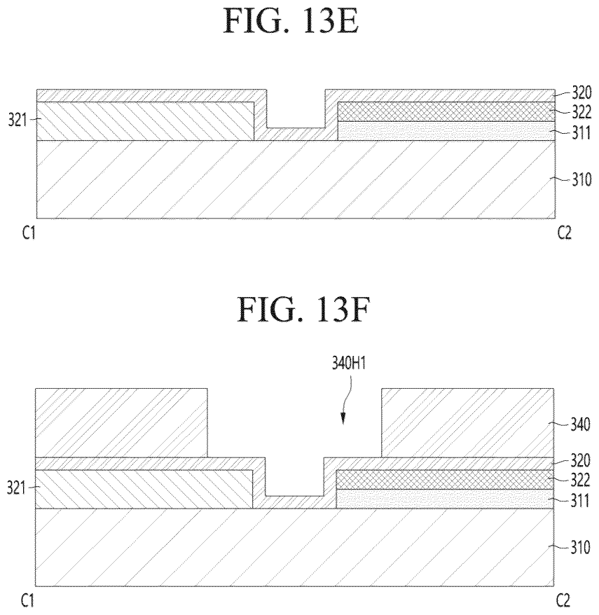

FIGS. 13A to 13F illustrate a method for manufacturing a display substrate according to the first embodiment.

As illustrated in FIG. 13A, a first assembling wiring 321 may be formed on the substrate 310.

Although not illustrated, after a metal film and a photosensitive film are formed on the substrate 310, the photosensitive film may be patterned to form a photosensitive pattern. Thereafter, an etching process is performed using the photosensitive pattern as a mask, so that the remaining metal film except for the metal film corresponding to the photosensitive pattern can be removed. The remaining metal film can be formed as the first assembling wiring 321.

As illustrated in FIG. 13B, an adjustment member 311 can be formed on the substrate 310.

The adjustment member 311 can be formed on the entire area of the substrate 310. The adjustment member 311 can be formed on the first assembling wiring 321. The adjustment member 311 can be made of an insulating material. The adjustment member 311 can be made of a dielectric material.

As illustrated in FIG. 13C, a second assembling wiring 322 can be formed on the adjustment member 311.

Although not shown, after a metal film and a photosensitive film are formed on the adjustment member 311, the photosensitive film may be patterned to form a photosensitive pattern. Afterwards, an etching process may be performed using the photosensitive pattern as a mask, so that the remaining metal film except for the metal film corresponding to the photosensitive pattern may be removed. The remaining metal film may be formed as a second assembling wiring 322.

The second assembling wiring 322 may be horizontally spaced from the first assembling wiring 321. The first assembling wiring 321 and the second assembling wiring 322 may be members for forming the DEP force for assembling a semiconductor light-emitting element during self-assembly, and must not be electrically short-circuited.

According to an embodiment, since the first assembling wiring 321 and the second assembling wiring 322 are formed on different layers, an electrical short may not occur between the first assembling wiring 321 and the second assembling wiring 322. That is, since the adjustment member 311 covers the first assembling wiring 321, the first assembling wiring 321 and the second assembling wiring 322 can be electrically insulated by the adjustment member 311.

Therefore, if the electrical insulation performance of the adjustment member 311 is secured, the second assembling wiring 322 may be disposed to be horizontally moved further to the left than that illustrated in FIG. 13C. However, considering the pattern process margin for forming the second assembling wiring 322, the second assembling wiring 322 may be disposed to be spaced apart from the adjustment member 311 disposed on the side portion of the first assembling wiring 321.

Nevertheless, since the electrical short between the first assembling wiring 321 and the second assembling wiring 322 is prevented by the adjustment member 311, the second assembling wiring 322 can be formed so that the distance L1 from the first assembling wiring 321 is 3.5 μm or less. Therefore, even if the size of the semiconductor light-emitting element is reduced to 5 μm or less in order to reduce material costs and secure price competitiveness, the gap L1 between the first assembling wiring 321 and the second assembling wiring 322 in the assembly hole of each of the plurality of sub-pixels (PX1, PX2, PX3 in FIG. 9) can be designed to be 3.5 μm or less, so that the semiconductor light-emitting element with the reduced size can be stably assembled to improve the assembly rate and the lighting rate.

As shown in FIG. 13D, after the photosensitive pattern is removed, an etching process is performed using the second assembling wiring 322 as a mask, so that the remaining adjustment members 311 except for the adjustment member 311 corresponding to the second assembling wiring 322 can be removed.

Therefore, the adjustment member 311 can have the same shape as the second assembling wiring 322. The width W12 of the adjustment member 311 may be the same as the width W11 of the second assembling wiring 322.

The thickness T11 of the first assembling wiring 321 may be the sum of the thickness T12 of the second assembling wiring 322 and the thickness T13 of the adjustment member 311.

The adjustment member 311 may serve to adjust the upper surface of the second assembling wiring 322 to be positioned on the same horizontal surface as the upper surface of the first assembling wiring 321. For example, the thickness T13 of the adjustment member 311 may be a value obtained by subtracting the thickness T12 of the second assembling wiring 322 from the thickness T11 of the first assembling wiring 321. Accordingly, by forming the adjustment member 311 under the second assembling wiring 322, the upper surface of the second assembling wiring 322 can be positioned on the same horizontal surface as the upper surface of the first assembling wiring 321 by the adjustment member 311.

The adjustment member 311 can have the same area as the second assembling wiring 322, but is not limited thereto. When wet etching is performed, the adjustment member 311 corresponding to the edge of the second assembling wiring 322 can be formed by over-etching that is etched further inward.

Meanwhile, the photosensitive pattern may not be removed, and the etching process may be performed using the photosensitive pattern as a mask, so that the second assembling wiring 322 and the adjustment member 311 corresponding to the photosensitive pattern can be formed.

According to the embodiment, an insulation layer 320 may be formed on the first assembling wiring 321 and the second assembling wiring 322, and since the upper surface of the first assembling wiring 321 and the upper surface of the second assembling wiring 322 are positioned on the same horizontal surface, by forming a symmetrical or uniform DEP force within the assembly hole 340H1, 340H2 and 340H3 of each of the plurality of sub-pixels PX1, PX2 and PX3 by the first assembling wiring 321 and the second assembling wiring 322, the assembly rate and lighting rate can be significantly improved.

As illustrated in FIG. 13E, an insulation layer 320 can be formed on the substrate 310.

The insulation layer 320 can be formed on the entire area of the substrate 310. The insulation layer 320 can be formed on the first assembling wiring 321. The insulation layer 320 can be formed on the second assembling wiring 322. The insulation layer 320 can be formed on the substrate 310 between the first assembling wiring 321 and the second assembling wiring 322.

According to an embodiment, since the first assembling wiring 321 and the second assembling wiring 322 are positioned on the same horizontal surface, when the insulation layer 320 is formed on the first assembling wiring 321 and the second assembling wiring 322, the upper surface of the insulation layer 320 can also have a horizontal surface. When semiconductor light-emitting elements (150-1, 150-2, 150-3 of FIG. 18) are assembled on the assembly holes 340H1, 340H2, and 340H3 of the plurality of sub-pixels PX1, PX2, and PX3, respectively, during self-assembly, the semiconductor light-emitting element 150-1, 150-2, and 150-3 can be disposed on the insulation layer 320 having a horizontal surface without tilt. Accordingly, the semiconductor light-emitting elements 150-1, 150-2, and 150-3 assembled in the assembly holes 340H1, 340H2, and 340H3 uniformly, respectively, may receive the DEP force formed by the first assembling wiring 321 and the second assembling wiring 322 so as not to fall out of the assembly holes 340H1, 340H2, and 340H3, so that the assembly rate can be improved. An increase in the assembly rate can lead to an increase in the lighting rate.

As illustrated in FIG. 13F, a partition wall 340 comprising the assembly hole 340H1 can be formed on the insulation layer 320.

An insulating film can be formed on the insulation layer 320, and the insulating film can be partially removed to form the assembly hole 340H1.

The shape of the assembly hole 340H1 can be formed to correspond to the shape of the semiconductor light-emitting element (150-1 of FIG. 18). The size of the assembly hole can be greater than the size of the semiconductor light-emitting element, so that the semiconductor light-emitting element can be easily assembled into the assembly hole. When the semiconductor light-emitting element is assembled into the assembly hole, the outer surface of the semiconductor light-emitting element can be spaced apart from the inner surface of the assembly hole. For example, the spacing between the outer surface of the semiconductor light-emitting element and the inner surface of the assembly hole can be 1.5 μm or less, but is not limited thereto.

For example, the diameter of the assembly hole can be greater than the spacing L1 between the first assembling wiring 321 and the second assembling wiring 322. Accordingly, a part of the first assembling wiring 321 and a part of the second assembling wiring 322 can vertically overlap with the assembly hole. The DEP force can be formed in the assembly hole by the first assembling wiring 321 and the second assembling wiring 322 that are vertically overlapped with the assembly hole.

Meanwhile, the DEP force may be also formed by the first assembling wiring and the second assembling wiring 322 that are vertically overlapped with the partition wall 340, but this the DEP force may be blocked by the partition wall 340 having a thick thickness, so that the DEP force may not be formed on the upper surface of the partition wall 340. Therefore, even if a large number of semiconductor light-emitting elements are moved on the partition wall 340 during self-assembly, they are not affected by the DEP force and can move freely without the constraints of the DEP force. In this way, the semiconductor light-emitting elements that are moving can be inserted into the assembly hole under the influence of the large the DEP force formed in the assembly hole and be continuously fixed in the assembly hole by the DEP force.

Meanwhile, assembly holes 340H1, 340H2, and 340H3 may be formed in a plurality of sub-pixels (PX1, PX2, and PX3 in FIG. 9), respectively.

### Second Embodiment

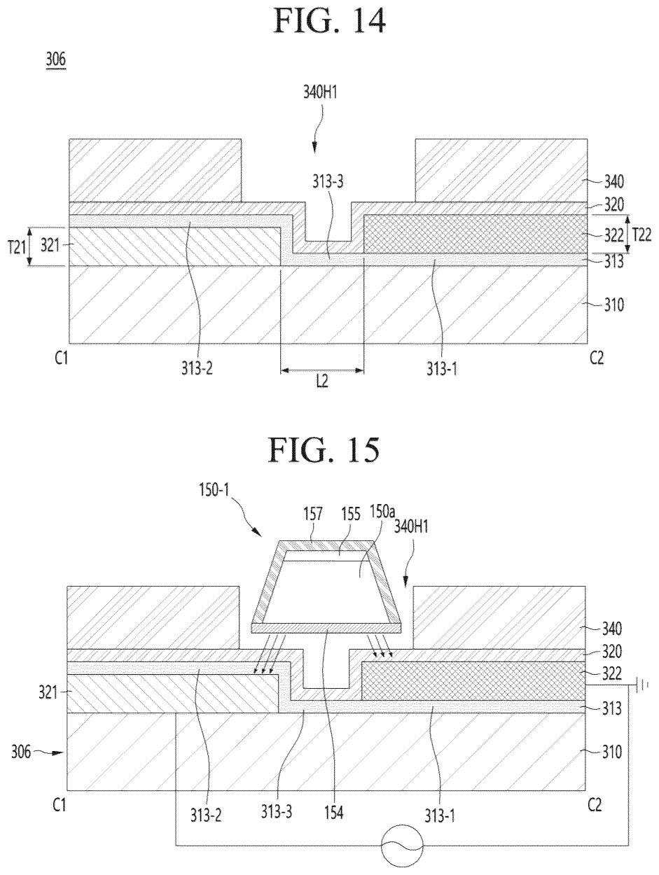

FIG. 14 is a cross-sectional view illustrating a display substrate according to a second embodiment.

The second embodiment is the same as the first embodiment except for the adjustment member 313. In the second embodiment, components having the same structure, shape, and/or function as those in the first embodiment are given the same drawing reference numerals, and detailed descriptions are omitted.

Referring to FIG. 14, the display substrate 306 according to the second embodiment may comprise a first assembling wiring 321, a second assembling wiring 322, an adjustment member 313, an insulation layer 320, and a partition wall 340.

In the embodiment, the first assembling wiring 321 and the second assembling wiring 322 may be disposed on different layers. The gap L2 between the first assembling wiring 321 and the second assembling wiring 322 may be 3.5 μm or less.

In the first embodiment (FIG. 10), the adjustment member 311 is disposed only under the second assembling wiring 322, whereas in the second embodiment (FIG. 14), the adjustment member 313 may be formed more widely.

The adjustment member 313 may be a member that adjusts the permittivity contributing to the DEP force. For example, the adjustment member 313 may be a member for lowering the DEP force formed on the first assembling wiring 321.

The adjustment member 313 may comprise a first adjustment region 313-1, a second adjustment region 31-2, and a third adjustment region 313-3. The first adjustment region 313-1 may be disposed under the second assembling wiring 322, the second adjustment region 31-2 may be disposed on the first assembling wiring 321, and the third adjustment region 313-3 may connect the first adjustment region 313-1 and the second adjustment region 31-2.

For example, the first adjustment region 313-1 may be disposed between the substrate 310 and the second assembling wiring 322, the second adjustment region 31-2 may be disposed between the first assembling wiring 321 and the insulation layer 320, and the third adjustment region 313-3 may be disposed between the substrate 310 and the insulation layer 320.

The lower surface of the first assembling wiring 321 and the lower surface of the first adjustment region 313-1 may be positioned on a first horizontal surface, and the upper surface of the second adjustment region 313-2 and the upper surface of the second assembling wiring 322 may be positioned on a second horizontal surface parallel to the first horizontal surface. The sum of the thickness of the first assembling wiring 321 and the thickness of the first adjustment region 313-1 may be equal to the sum of the thickness of the second adjustment region 313-2 and the thickness of the second assembling wiring 322.

For example, the adjustment member 313 and the insulation layer 320 may be positioned on the first assembling wiring 321, and the insulation layer 320 may be positioned on the second assembling wiring 322. Accordingly, the DE force formed on the first assembling wiring 321 may be formed by the permittivity of the insulation layer 320 as well as the permittivity of the adjustment member 313. The DEP force formed on the second assembling wiring 322 may be formed by the permittivity of the insulation layer 320. Since the DEP force formed on the first assembling wiring 321 is greater than the DEP force formed on the second assembling wiring 322, the DEP force may be formed asymmetrically or non-uniformly within the assembly hole.

The adjustment member 313 may comprise a dielectric layer. The adjustment member 313 may be made of a dielectric material. The permittivity of the adjustment member 313 may be smaller than the permittivity of the insulation layer 320. For this purpose, the material of the adjustment member 313 may be made of a material having a low permittivity.

Meanwhile, the DEP force may also be affected by the thickness of the adjustment member 313. The thickness of the adjustment member 313 may be smaller than the thickness of the insulation layer 320. The thickness of the adjustment member 313 on the first assembling wiring 321 may be smaller than the thickness of the insulation layer 320. The thickness of the adjustment member 313 on the first assembling wiring 321 in the assembly hole may be smaller than the thickness of the insulation layer 320.

The thickness T21 of the first assembling wiring 321 and the thickness T22 of the second assembly backing may be the same.

The applicant conducted an experiment on the symmetry of the force acting on the semiconductor light-emitting element by considering the material or thickness of the adjustment member 313 and the insulation layer 320.

The material or thickness of the adjustment member 313 and the insulation layer 320 used in the experiment can be shown in Table 1.

TABLE 1

| | ADJUSTMENT | | INSULATING | |
|---|---|---|---|---|
| | MEMBER | | LAYER | |
| | 313 | | 320 | |
| | | THICKNESS | | THICKNESS |
| SAMPLE | MATERIAL | (nm) | MATERIAL | (nm) |
| #1 | SiO₂ | 100 | SiO₂ | 100 |
| #2 | SiN | 100 | SiN | 100 |
| #3 | SiO₂ | 100 | SiN | 100 |
| #4 | SiN | 100 | SiO₂ | 100 |
| #5 | SiN | 50 | SiO₂ | 100 |

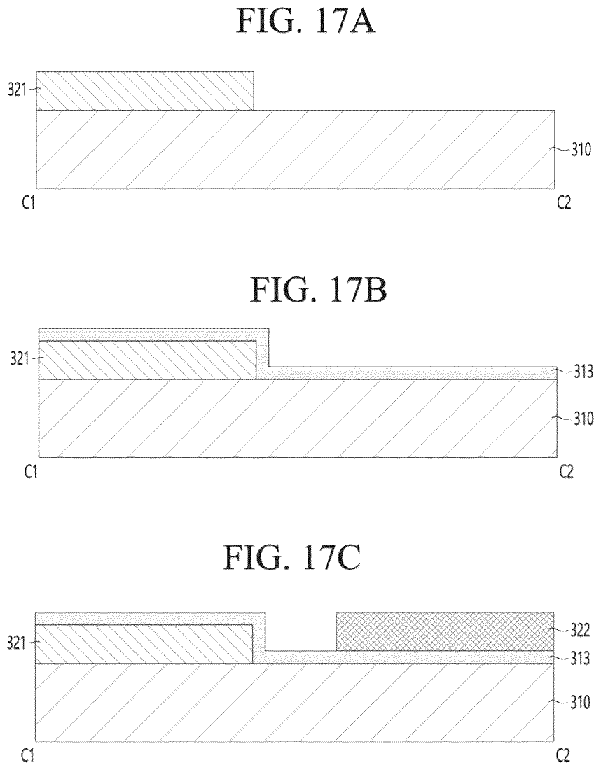

The symmetry distribution tested using Table 1 is shown in FIG. 16. As shown in FIG. 16, when the third sample (#3) was used, it can be seen that the unevenness of the DEP force between the first assembling wiring 321 and the second assembling wiring 322 was the most severe. It can be seen that the DEP force becomes more uniform in the order of the first sample (#1), the second sample (#2), the fourth sample (#4), and the fifth sample (#5). That is, when the adjustment member 313 comprising SiN and having a thickness of 50 nm and the insulation layer 320 comprising SiO2 and having a thickness of 100 nm are used by the fifth sample (#5), it can be seen that the DEP force on the first assembling wiring 321 and the DEP force on the second assembling wiring 322 become almost uniform.

In the embodiment, the gradient ratio of the DEP force between the first assembling wiring 321 and the second assembling wiring 322 can be 50% or less. In the embodiment, the gradient ratio of the DEP force between the first assembling wiring 321 and the second assembling wiring 322 can be 30% or less. The gradient ratio can indicate the degree of non-uniformity of the DEP force between the first assembling wiring 321 and the second assembling wiring 322. A lower gradient ratio can mean that the DEP force between the first assembling wiring 321 and the second assembling wiring 322 becomes uniform. For example, when the gradient ratio is 0, the DEP force on the first assembling wiring 321 and the DEP force on the second assembling wiring 322 may be the same, which may mean that the DEP force between the first assembling wiring 321 and the second assembling wiring 322 can be symmetrical or uniform.

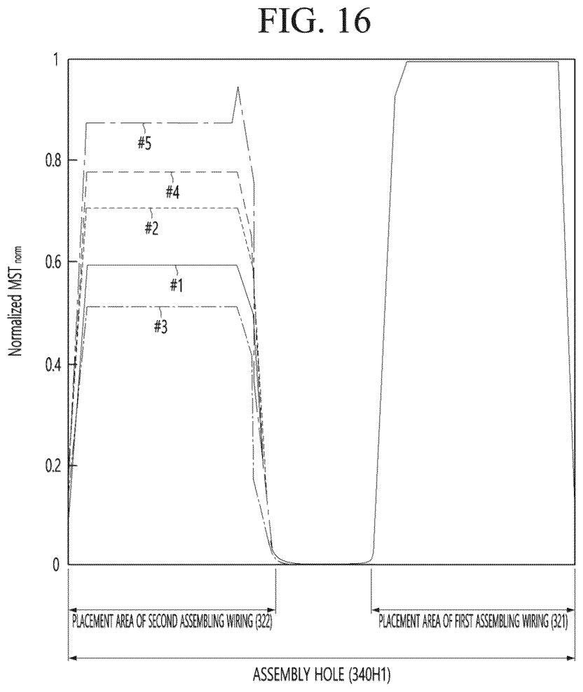

As illustrated in FIG. 15, a semiconductor light-emitting element 150-1 can be assembled on a display substrate 306 according to the second embodiment by a self-assembly method. The DEP force can be formed within an assembly hole by an AC voltage supplied to the first assembling wiring 321 and the second assembling wiring 322. Since an adjustment member 313 is disposed between the first assembling wiring 321 and the insulation layer 320, the DEP force can be formed symmetrically or uniformly within the assembly hole. In this case, the semiconductor light-emitting element 150-1 can be assembled in a fixed position without being tilted to one side by the DEP force uniformly formed within the assembly hole and may not fall out of the assembly hole.

According to the embodiment, the adjustment member 313 may be disposed on the first assembling wiring 321, and the permittivity of the adjustment member 313 may be designed to be smaller than the permittivity of the insulation layer 320, or the thickness of the adjustment member 313 may be designed to be smaller than the thickness of the insulation layer 320, so that the gradient ratio of the DEP force between the first assembling wiring 321 and the second assembling wiring 322 can be 50% or less, thereby reducing the gradient ratio of the DEP force, and changing the asymmetry or non-uniformity of the DEP force within the assembly hole to symmetry or uniformity. Accordingly, the problem of the semiconductor light-emitting element being pushed out to a place other than the correct position within the assembly hole during self-assembly or the problem of falling out within the assembly hole can be solved, thereby dramatically improving the assembly rate and the lighting rate.

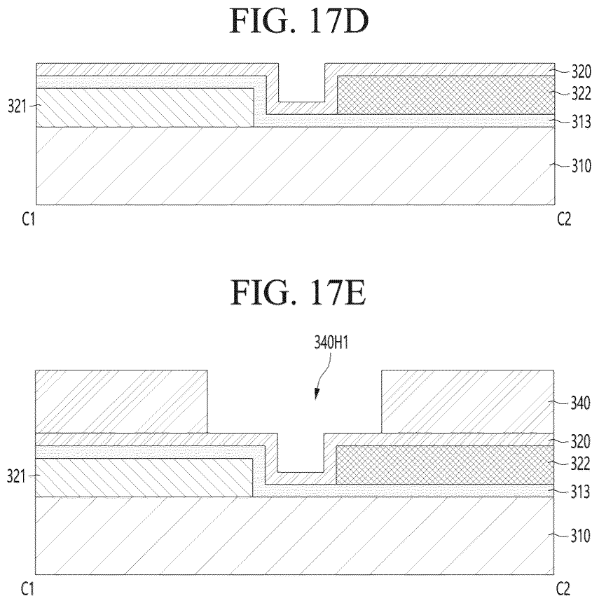

FIGS. 17A to 17E illustrate a method of manufacturing a display substrate according to the second embodiment.

Since FIGS. 17A to 17C are identical to FIGS. 13A to 13C and have been described above, detailed descriptions thereof will be omitted.

As illustrated in FIG. 17D, an insulation layer 320 may be formed on a substrate 310.

The insulation layer 320 may be formed on a second assembling wiring 322. The insulation layer 320 may be formed on an adjustment member 313 corresponding to the first assembling wiring 321. The insulation layer 320 may be formed on an adjustment member 313 between the first assembling wiring 321 and the second assembling wiring 322.

As illustrated in FIG. 17E, a partition wall 340 comprising an assembly hole 340H1 may be formed on the insulation layer 320.

An insulating film is formed on the insulation layer 320, and the insulating film is partially removed, so that an assembly hole 340H1 can be formed.

FIG. 17E is the same as FIG. 13F and has been described above, so that a detailed description is omitted.

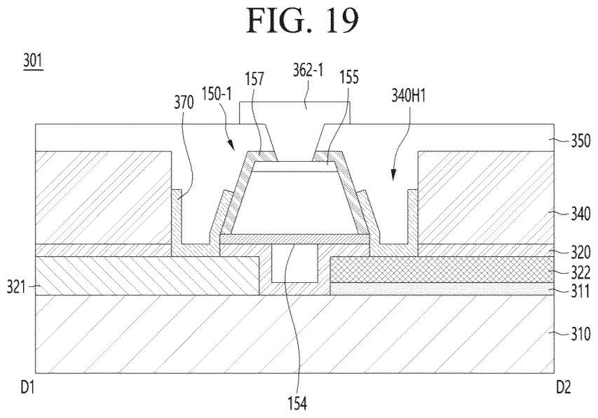

FIG. 18 is a plan view illustrating a display device according to an embodiment. FIG. 19 is a cross-sectional view cut along the D1-D2 line of the first sub-pixel in the display device according to the embodiment of FIG. 18.

After semiconductor light-emitting elements 150-1, 15-2 and 150-3 are assembled on the display substrate (305 of FIGS. 9 and 10) according to the first embodiment or the display substrate (306 of FIG. 14) according to the second embodiment, the display device 301 according to the embodiment can be manufactured by electrically connecting the semiconductor light-emitting elements 150-1, 15-2 and 150-3 through a post-process.

Although not shown in the drawing, the display substrate (306 of FIG. 14) according to the second embodiment can also be applied in the same manner to FIG. 19.

Referring to FIG. 18 and FIG. 19, the display device 301 according to the embodiment may comprise a substrate 310, a plurality of first assembling wirings 321, a plurality of adjustment members 311, a plurality of second assembling wirings 322, a first insulation layer 320, a partition wall 340, a plurality of semiconductor light-emitting elements 150-1, 150-2, and 150-3, a second insulation layer 350, a plurality of connection electrodes 370, and a plurality of signal lines SL1, SL2, SL3, and SL4.

The first insulation layer 320 may be an insulation layer of the display substrate 305 according to the first embodiment illustrated in FIG. 10.

Since the substrate 310, the plurality of first assembling wirings 321, the plurality of second assembling wirings 322, and the partition wall 340 have been described above, a detailed description thereof will be omitted.

A plurality of sub-pixels PX1, PX2, and PX3 may be defined on the substrate 310. In the drawing, the first sub-pixel PX1, the second sub-pixel PX2, and the third sub-pixel PX3 are illustrated as being arranged along the second direction Y, but is not limited thereto.

A first sub-pixel column comprising a plurality of first sub-pixels PX1, a second sub-pixel column comprising a plurality of second sub-pixels PX2, and a third sub-pixel column comprising a plurality of third sub-pixels PX3 may be disposed parallel to each other along the first direction X.

At least one assembly hole 340H1, 340H2, and 340H3 may be provided in each of the first sub-pixel PX1, the second sub-pixel PX2, and the third sub-pixel PX3.

Through the self-assembly process, the plurality of semiconductor light-emitting elements 150-1, 150-2 and 150-3 can be assembled into the assembly holes 340H1, 340H2 and 340H3, respectively, by the DEP force formed between the first assembling wiring 321 and the second assembling wiring 322 in the plurality of sub-pixels PX1, PX2 and PX3, respectively. For example, the first semiconductor light-emitting element 150-1 can be assembled into the first assembly hole 340H1 by the DEP force formed between the first assembling wiring 321 and the second assembling wiring 322 provided in the first sub-pixel PX1. For example, the second semiconductor light-emitting element 150-2 can be assembled into the second assembly hole 340H2 by the DEP force formed between the first assembling wiring 321 and the second assembling wiring 322 provided in the second sub-pixel PX2. For example, the third semiconductor light-emitting element 150-3 can be assembled into the third assembly hole 340H3 by the DEP force formed between the first assembling wiring 321 and the second assembling wiring 322 provided in the third sub-pixel PX3.

The sizes of the assembly holes 340H1, 340H2, and 340H3 can be determined by considering the tolerance margin for forming the assembly holes 340H1, 340H2, and 340H3, and the margin for easily assembling the semiconductor light-emitting elements 150-1, 150-2, and 150-3 within the assembly holes 340H1, 340H2, and 340H3. For example, the sizes of the assembly holes 340H1, 340H2, and 340H3 can be greater than the sizes of the semiconductor light-emitting elements 150-1, 150-2, and 150-3. For example, when the semiconductor light-emitting elements 150-1, 150-2 and 150-3 are assembled at the center of the assembly holes 340H1, 340H2 and 340H3, the distance between the outer side surface of the semiconductor light-emitting elements 150-1, 150-2 and 150-3 and the inner side surface of the assembly holes 340H1, 340H2 and 340H3 may be 2 μm or less, but is not limited thereto.

For example, the assembly holes 340H1, 340H2 and 340H3 may have shapes corresponding to the shapes of the semiconductor light-emitting elements 150-1, 150-2 and 150-3. For example, when the semiconductor light-emitting elements 150-1, 150-2 and 150-3 are circular, the assembly holes 340H1, 340H2 and 340H3 may also be circular. For example, when the semiconductor light-emitting elements 150-1, 150-2, and 150-3 are rectangular, the assembly holes 340H1, 340H2, and 340H3 may also be rectangular.

As an example, the assembly holes 340H1, 340H2, and 340H3 in the first sub-pixel PX1, the second sub-pixel PX2, and the third sub-pixel PX3, respectively, may have the same shape, i.e., a circle. In this case, the first semiconductor light-emitting element 150-1 disposed in the first sub-pixel PX1, the second semiconductor light-emitting element 150-2 disposed in the second sub-pixel PX2, and the third semiconductor light-emitting element 150-3 disposed in the third sub-pixel PX3 may have shapes corresponding to the assembly holes 340H1, 340H2, and 340H3, i.e., a circle.

In this way, when the assembly holes 340H1, 340H2 and 340H3 of the first sub-pixel PX1, the second sub-pixel PX2 and the third sub-pixel PX3 have the same shape, the first semiconductor light-emitting element 150-1, the second semiconductor light-emitting element 150-2 and the third semiconductor light-emitting element 150-3 can be sequentially assembled into the assembly holes 340H1, 340H2 and 340H3 of the corresponding sub-pixels PX1, PX2 and PX3, respectively, but are not limited thereto. For example, the first semiconductor light-emitting element 150-1 may be assembled into the first assembly hole 340H1 of the first sub-pixel PX1 of the substrate 310, the second semiconductor light-emitting element 150-2 may be assembled into the second assembly hole 340H2 of the second sub-pixel PX2 of the substrate 310, and the third semiconductor light-emitting element 150-3 may be assembled into the third assembly hole 340H3 of the third sub-pixel PX3 of the substrate 310. In this case, the shapes of the first semiconductor light-emitting element 150-1, the second semiconductor light-emitting element 150-2, and the third semiconductor light-emitting element 150-3 may be the same, but are not limited thereto. The assembly holes 340H1, 340H2, and 340H3 may have shapes corresponding to the shapes of the first semiconductor light-emitting element 150-1, the second semiconductor light-emitting element 150-2, and the third semiconductor light-emitting element 150-3, respectively, but may have sizes greater than the sizes of the first semiconductor light-emitting element 150-1, the second semiconductor light-emitting element 150-2, and the third semiconductor light-emitting element 150-3, respectively.

As another example, the assembly holes 340H1, 340H2, and 340H3 in the first sub-pixel PX1, the second sub-pixel PX2, and the third sub-pixel PX3, respectively, may have different shapes. For example, the first assembly hole 340H1 in the first sub-pixel PX1 may have a circular shape, the second assembly hole 340H2 in the second sub-pixel PX2 may have a first oval shape having a first minor axis and a first major axis, and the third assembly hole 340H3 in the third sub-pixel PX3 may have a second oval shape having a second minor axis smaller than the first minor axis and a second major axis greater than the first major axis. In this case, the first semiconductor light-emitting element 150-1 may have a shape corresponding to the first assembly hole 340H1 of the first sub-pixel PX1, that is, a circular shape, the second semiconductor light-emitting element 150-2 may have a shape corresponding to the second assembly hole 340H2 of the second sub-pixel PX2, that is, a first oval shape, and the third semiconductor light-emitting element 150-3 may have a shape corresponding to the third assembly hole 340H3 of the third sub-pixel PX3, that is, a second oval shape.

By means of the assembly holes 340H1, 340H2 and 340H3 having different shapes and the first to third semiconductor light-emitting elements 150-1, 150-2 and 150-3 having shapes corresponding to the assembly holes 340H1, 340H2 and 340H3, the first to third semiconductor light-emitting elements 150-1, 150-2 and 150-3 can be simultaneously assembled into the corresponding assembly holes 340H1, 340H2 and 340H3 during self-assembly. That is, even if the first semiconductor light-emitting element 150-1, the second semiconductor light-emitting element 150-2, and the third semiconductor light-emitting element 150-3 are mixed in the fluid 1200 for self-assembly, the semiconductor elements 150-1, 150-2, and 150-3 corresponding to the assembly holes 340H1, 340H2, and 340H3 of the first sub-pixel PX1, the second sub-pixel PX2, and the third sub-pixel PX3 on the substrate 310 can be assembled. That is, the first semiconductor light-emitting element 150-1 having a shape corresponding to the shape of the first assembly hole 340H1 of the first sub-pixel PX1 can be assembled into the first assembly hole 340H1 of the first sub-pixel PX1. The second semiconductor light-emitting element 150-2 having a shape corresponding to the shape of the second assembly hole 340H2 can be assembled into the second assembly hole 340H2 of the second sub-pixel PX2. The third semiconductor light-emitting element 150-3 having a shape corresponding to the shape of the third assembly hole 340H3 of the third sub-pixel PX3 can be assembled into the third assembly hole 340H3 of the third sub-pixel PX3. Accordingly, since the first semiconductor light-emitting element 150-1, the second semiconductor light-emitting element 150-2, and the third semiconductor light-emitting element 150-3 having different shapes are assembled into the assembly holes 340H1, 340H2, and 340H3 corresponding to their own shapes, assembly failure can be prevented.

Meanwhile, the first semiconductor light-emitting element 150-1 may comprise a light-emitting portion 150a, a first electrode 154 under the light-emitting portion 150a, a second electrode 155 on the light-emitting portion 150a, and a passivation layer 157 surrounding the light-emitting portion 150a.

The light-emitting portion 150a may a place where light is generated, and may comprise at least one or more first conductivity type semiconductor layer, an active layer, and at least one or more second conductivity type semiconductor layer. For example, the first conductivity type semiconductor layer may comprise a first dopant, such as Si, and the second conductivity type semiconductor layer may comprise a second dopant, such as Mn.

Meanwhile, the connection electrode 370 may be disposed in the assembly holes 340H1, 340H2, and 340H3. For example, the connection electrode 370 may be disposed around the semiconductor light-emitting elements 10-1, 150-2, and 150-3 within the assembly holes 340H1, 340H2, and 340H3.

The connection electrode 370 may connect the lower side of the semiconductor light-emitting element to at least one of the first assembling wiring 321 and the second assembling wiring 322.

Although not shown, the connection electrode 370 may also be connected to the second semiconductor light-emitting element 150-2 of the second sub-pixel PX2 or the third semiconductor light-emitting element 150-3 of the third sub-pixel PX3. The second semiconductor light-emitting element 150-2 or the third semiconductor light-emitting element 150-3 may have the same structure as the first semiconductor light-emitting element 150-1 except for the shape.

In addition, as shown in FIG. 19, the connection electrode 370 may be disposed along the periphery of the semiconductor light-emitting element 150-1, 150-2, and 150-3 within the assembly hole 340H1, so that the partition wall 340 and the semiconductor light-emitting element 150-1, 150-2, and 150-3 can be firmly fixed by the connection electrode 370, thereby enhancing the fixing strength.

Meanwhile, the second insulation layer 350 may be disposed on the partition wall 340 to protect the first semiconductor light-emitting element 150-1. The second insulation layer 350 may be disposed in the assembly hole 340H1 around the semiconductor light-emitting element 150-1 to firmly fix the semiconductor light-emitting element 150-1. In addition, the second insulation layer 350 may be disposed on the semiconductor light-emitting element 150-1 to protect the semiconductor light-emitting element 150-1 from external impact and prevent the semiconductor light-emitting element 150-1 from being contaminated by foreign substances.

The second insulation layer 350 can serve as a planarization layer that allows a layer formed in a subsequent process to be formed with a constant thickness. Accordingly, the upper surface of the second insulation layer 350 can have a flat surface. The second insulation layer 350 can be formed of an organic material or an inorganic material. Accordingly, the electrode wirings 362-1, 362-2, and 362-3 can be easily formed without a short circuit on the upper surface of the second insulation layer 350 having a flat surface.

The plurality of electrode wirings 362-1, 362-2, and 362-3 can be disposed on the upper sides of the plurality of semiconductor light-emitting elements 150-1, 150-2, and 150-3, respectively. The first sub-pixel PX1, the second sub-pixel PX2, and the third sub-pixel PX3 can comprise the electrode wirings 362-1, 362-2, and 362-3, respectively.

For example, the electrode wirings 362-1, 362-2, and 362-3 can be disposed on the upper side of the first semiconductor light-emitting element 150-1 disposed in the first sub-pixel PX1. The first electrode wiring 362-1 may be connected to the second side of the first semiconductor light-emitting element 150-1 through the first contact hole 350H1. For example, the second electrode wiring 362-2 may be disposed on the upper side of the second semiconductor light-emitting element 150-2 disposed in the second sub-pixel PX2. The second electrode wiring 362-2 may be connected to the second side of the second semiconductor light-emitting element 150-2 through the second contact hole 350H2. For example, the third electrode wiring 362-3 may be disposed on the upper side of the third semiconductor light-emitting element 150-3 disposed in the third sub-pixel PX3. The third electrode wiring 362-3 may be connected to the second side of the third semiconductor light-emitting element 150-3 through the third contact hole 350H3.

The first electrode wiring 362-1 may be disposed on the second insulation layer 350. For example, the first electrode wiring 362-1 may be made of a transparent conductive material that allows light to pass through. For example, the first electrode wiring 362-1 may comprise ITO, IZO, etc., but is not limited thereto.

Although not illustrated, the second electrode wiring 362-2 and the third electrode wiring 362-3 may also be disposed on the second insulation layer 350.

Meanwhile, in each of the plurality of sub-pixels PX1, PX2, and PX3, the first assembling wiring 321 and/or the second assembling wiring 322 may be used as the first electrode wiring, and the electrode wirings 362-1, 362-2, and 362-3 may be the second electrode wirings.

Accordingly, the first semiconductor light-emitting element 150-1 can emit first color light, for example, red light, by a voltage applied between the first assembling wiring 321 and/or the second assembling wiring 322 and the electrode wirings 362-1, 362-2, and 362-3.

Meanwhile, the display device 301 according to the embodiment can comprise a plurality of signal lines SL1, SL2, SL3, and SL4. The plurality of signals can comprise a first signal line SL1, a second signal line SL2, a third signal line SL3, and a fourth signal line SL4. The plurality of signal lines SL1, SL2, SL3, and SL4 can be disposed on the same layer.

The plurality of signal lines SL1, SL2, SL3, and SL4 can be disposed in different layers from the electrode wirings 362-1, 362-2, and 362-3. Accordingly, the plurality of signal lines SL1, SL2, SL3, and SL4 and the electrode wirings 362-1, 362-2, and 362-3 can be electrically connected through the plurality of contact holes 351H1, 351H2, and 351H3. For example, the first signal line SL1 and the first electrode wiring 362-1 can be electrically connected through the first contact hole 351H1. For example, the second signal line SL2 and the second electrode wiring 362-2 can be electrically connected through the second contact hole 351H2. For example, the third signal line SL3 and the third electrode wiring 362-3 may be electrically connected through the third contact hole 351H3. For example, the fourth signal line SL4 and the first assembling wiring 321 and/or the second assembling wiring 322 may be electrically connected through the contact hole 352.

The plurality of signal lines SL1, SL2, SL3, and SL4 may be disposed in different layers from the first assembling wiring 321 and the second assembling wiring 322.

Meanwhile, the first signal line SL1 may be electrically connected to the plurality of first sub-pixels PX1. For example, the first signal line SL1 may be electrically connected to the second electrode 155 of the first semiconductor light-emitting element 150-1 through the first electrode wiring 362-1 of each of the plurality of first sub-pixels PX1.

The second signal line SL2 may be electrically connected to a plurality of second sub-pixels PX2. For example, the second signal line SL2 may be electrically connected to a second electrode 155 of a second semiconductor light-emitting element 150-2 through a second electrode wiring 362-2 of each of the plurality of second sub-pixels PX2.

The third signal line SL3 may be electrically connected to a plurality of third sub-pixels PX3. For example, the third signal line SL3 may be electrically connected to a second electrode 155 of a third semiconductor light-emitting element 150-3 through a third electrode wiring 362-3 of each of the plurality of third sub-pixels PX3.

The fourth signal line SL4 may be commonly connected to the first sub-pixel PX1, the second sub-pixel PX2, and the third sub-pixel PX3. For example, the fourth signal line SL4 may be electrically connected to the first electrode 154 of the first semiconductor light-emitting element 150-1 through the first assembling wiring 321 and/or the second assembling wiring 322 of the first sub-pixel PX1. For example, the fourth signal line SL4 may be electrically connected to the first electrode 154 of the second semiconductor light-emitting element 150-2 through the first assembling wiring 321 and/or the second assembling wiring 322 of the second sub-pixel PX2. For example, the fourth signal line SL4 may be electrically connected to the first electrode 154 of the third semiconductor light-emitting element 150-3 through the first assembling wiring 321 and/or the second assembling wiring 322 of the third sub-pixel PX3.

For example, each of the first signal line SL1, the second signal line SL2, and the third signal line SL3 may be supplied with a positive voltage. For example, the fourth signal line SL4 may be grounded or supplied with a negative voltage. The positive voltages supplied to each of the first signal line SL1, the second signal line SL2, and the third signal line SL3 may be the same, but are not limited thereto.

For example, the first signal line SL1 connected to the first sub-pixel PX1 may be a high-potential voltage line VDDL as illustrated in FIG. 7. For example, the second signal line SL2 connected to the second sub-pixel PX2 and the third signal line SL3 connected to the third sub-pixel PX3 may also be a high-potential signal line VDDL to which a high-potential voltage (VDD of FIG. 6) is supplied. For example, the fourth signal line SL4 commonly connected to each of the first sub-pixel PX1, the second sub-pixel PX2, and the third sub-pixel PX3 may be a low-potential signal line VSSL to which a low-potential voltage (VSS of FIG. 6) is supplied.

Although not shown in the drawing, a driving transistor (DT of FIG. 7) may be provided between the first signal line SL1 and the first semiconductor light-emitting element 150-1 of the first sub-pixel PX1, the second signal line SL2 and the second semiconductor light-emitting element 150-2 of the second sub-pixel PX2, and the third signal line SL3 and the third semiconductor light-emitting element 150-3 of the third sub-pixel PX3. At this time, the gate terminal of the driving transistor DT can be connected to the data line Dj through the scan transistor ST.

Therefore, the first sub-pixel PXT, the second sub-pixel PX2, and the third sub-pixel PX3 can be provided with a scan transistor ST, a driving transistor DT, and semiconductor light-emitting elements 150-1, 150-2, and 150-3, respectively. At this time, the driving transistor DT is connected to the scan transistor ST and the semiconductor light-emitting elements 150-1, 150-2, and 150-3, and the scan transistor ST can be connected to the data line Dj. The driving transistors ST of the first sub-pixel PX1, the second sub-pixel PX2, and the third sub-pixel PX3 can be connected to the high-potential signal line VDDL, that is, the first to third signal lines SL1, SL2, and SL3, respectively. The semiconductor light-emitting elements 150-1, 150-2, and 150-3 of the first sub-pixel PX1, the second sub-pixel PX2, and the third sub-pixel PX3 may be connected to the low-voltage signal line VSSL, i.e., the fourth signal line SL4, respectively.

The current flowing through the driving transistor ST is different depending on the data voltage supplied to the data line Dj, and the light intensity, i.e., the luminance or gradation, of the semiconductor light-emitting elements 150-1, 150-2, and 150-3 of the first sub-pixel PX1, the second sub-pixel PX2, and the third sub-pixel PX3 is different due to the different currents, so that images having different brightness may be displayed.

Meanwhile, the display device described above may be a display panel. That is, in the embodiment, the display device and the display panel may be understood to have the same meaning. In an embodiment, the display device in a practical meaning may comprise a display panel and a controller (or processor) capable of controlling the display panel to display an image.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

### INDUSTRIAL APPLICABILITY

The embodiment can be adopted in the display field for displaying images or information. The embodiment can be adopted in the display field for displaying images or information using a semiconductor light-emitting element. The semiconductor light-emitting element can be a micro-level semiconductor light-emitting element or a nano-level semiconductor light-emitting element.

For example, the embodiment may be adopted in a TV, signage, a smart phone, a mobile phone, a mobile terminal, a HUD for an automobile, a backlight unit for a laptop computer, and a display device for VR or AR.

1. A display device, comprising:
a substrate;
a first assembling wiring on the substrate;
a second assembling wiring on the substrate;
an adjustment member under the second assembling wiring;
an insulation layer on the first assembling wiring and the second assembling wiring;
a partition wall comprising an assembly hole on the first assembling wiring and the second assembling wiring; and
a semiconductor light-emitting element in the assembly hole,
wherein the adjustment member comprises at least one or more conductive layer.

2. The display device of claim 1, wherein a thickness of the second assembling wiring is smaller than a thickness of the first assembling wiring.

3. The display device of claim 1, wherein a thickness of the adjustment member is a difference value between a thickness of the first assembling wiring and a thickness of the second assembling wiring.

4. The display device of claim 1, wherein the first assembling wiring and the adjustment member are disposed on the same layer.

5. The display device of claim 1, wherein the first assembling wiring and the second assembling wiring are disposed on different layers.

6. The display device of claim 1, wherein a lower surface of the first assembling wiring and a lower surface of the adjustment member are positioned on a first horizontal surface, and
wherein an upper surface of the first assembling wiring and an upper surface of the second assembling wiring are positioned on a second horizontal surface parallel to the first horizontal surface.

7. (canceled)

8. The display device of claim 1, wherein a width of the adjustment member is the same as a width of the second assembling wiring.

9-15. (canceled)

16. The display device of claim 1, wherein a gap between the first assembling wiring and the second assembling wiring is 3.5 μm or less.

17. The display device of claim 1, wherein the semiconductor light-emitting element has a diameter of 5 μm or less.

18. The display device of claim 1, comprising:
a connection electrode in the assembly hole,
wherein the connection electrode is configured to connect a lower side of the semiconductor light-emitting element to at least one of the first assembling wiring or the second assembling wiring.

19. The display device of claim 18, comprising:
an electrode wiring on the semiconductor light-emitting element,
wherein the electrode wiring is configured to be connected to an upper side of the semiconductor light-emitting element.
